(19) United States
(12) Patent Application Publication
(10) Pub. No.: US 2026/0081097 A1
(43) Pub. Date: Mar. 19, 2026

(54) METHOD FOR THE AUTOMATED MECHANICAL ADJUSTMENT OF A PARTICLE BEAM COLUMN, ASSOCIATED COMPUTER PROGRAM PRODUCT AND PARTICLE BEAM COLUMN

(71) Applicant: Carl Zeiss MultiSEM GmbH, Oberkochen (DE)

(72) Inventors: Steffen BALLING, Herbrechtingen (DE); Daniel SCHWARZ, Aalen (DE); Maximilian GNEDEL, Gundelfingen (DE); Samuel KLAMANDT, Ellwangen (DE); Bernd SCHINDLER, Aalen (DE); Maik HAEBERLEN, Aalen (DE)

(21) Appl. No.: 19/398,690

(22) Filed: Nov. 24, 2025

Related U.S. Application Data
(63) Continuation of application No. PCT/EP2024/025183, filed on Jun. 5, 2024.

(30) Foreign Application Priority Data
Jun. 7, 2023 (DE) 10 2023 115 085.5

(51) Int. Cl. H01J 37/147; H01J 37/22; H01J 37/28

(52) U.S. Cl. CPC H01J 37/1474; H01J 37/1478; H01J 37/222; H01J 37/28

(57) ABSTRACT

Multiple automated mechanical adjustment methods for a particle beam column are disclosed. By way of example, a beam generator, a condenser lens system, a detection system and an objective lens system can be adjusted relatively quickly and precisely. Mechanical adjustment methods may be combined with electrical adjustment methods.

### CROSS-REFERENCE TO RELATED APPLICATIONS

The present application is a continuation of, and claims benefit under 35 USC 120 to, international application No. PCT/EP2024/025183, filed Jun. 5, 2024, which claims benefit under 35 USC 119 of German Application No. 10 2023 115 085.5, filed Jun. 7, 2023. The entire disclosure of each of these applications is incorporated by reference herein.

### FIELD

The disclosure relates to a particle beam column, for example an electron beam column, for example a scanning electron microscope, or an ion beam column. The disclosure relates for example to a method for the automated mechanical adjustment of a particle beam column, to an associated computer program product and to an associated particle beam column.

### BACKGROUND

Particle beam columns, such as for example electron beam columns or ion beam columns, are known. One example is a scanning electron microscope in which a focused electron beam scans a region, to be imaged, of an object to be examined, and secondary electrons or backscattered electrons generated by the incident electron beam on the object are detected depending on the deflection of the focused particle beam, in order to generate or compute an electron-microscopic image of the scanned region of the object.

Basically, the primary particle beam is generated by a beam generator having a particle source, passes through beam-shaping elements such as for example a condenser lens, a stigmator or other beam-shaping elements and is then focused onto the object to be examined by an objective lens. In order to achieve a relatively high resolution of the particle beam column or of the particle beam microscope, the particle beam on the object is to be focused as well as possible, that is to say a region illuminated by the focused particle beam on the surface of the object (“beam spot”) is to be as small and round as possible. For this purpose, the particle beam microscope with its particle-optical components is adjusted with the objective that an image plane into which the particle source is imaged by the optical system coincides with the surface of the object. This may be achieved, in the case of an arrangement of the object at a given distance from the objective lens, by changing the focus setting of the particle beam microscope until the beam spot on the surface of the object is as small as possible. By way of example, the focus setting of the particle beam microscope may be altered by changing the excitation of the objective lens and/or by changing the kinetic energy of the particles in the particle beam when passing through the objective lens.

After the focus setting of the particle beam microscope has been set in this way, even further measures are taken, in general to improve the quality of the beam focus on the surface of the object. This includes adjusting the particle beam such that it passes substantially centrally through the objective lens. This is based on the thought that lens aberrations of an optical lens become ever more noticeable the further away the beam is from the optical axis of the lens when passing through the latter. Since the objective lens typically provides a majority of the refractive power used for imaging the particle source on the object surface, it is desirable in view of reducing the imaging aberrations involved during this imaging to adjust the beam relative to the objective lens such that it passes through the objective lens as centrally as possible. For this adjustment, the particle beam microscope or the particle beam column are known to comprise for example one or more deflection devices for displacing the particle beam within the objective lens and which is or are arranged in the beam path between the particle beam source and the objective lens. By changing the excitation of this deflection device or these deflection devices, it is possible to displace the location within a principal plane of the objective lens at which the centre of the particle beam passes through the principal plane.

In general, it is not easy to adjust the particle beam correctly. There are already a few known methods for this purpose.

By way of example, it is known to use the recording of particle-microscopic images with the particle beam microscope in at least two different focusing settings for the adjustment in order to set the optimum excitation of the deflection device based on an analysis of these recorded images or computed images. This is based on the following thoughts. If the particle beam passes centrally through the objective lens and is focused on the surface of the object, the recorded particle-microscopic image is substantially in focus. If the focus setting is slightly changed proceeding from this setting and if a particle-microscopic image is recorded for this altered setting, this image is only slightly less sharp in comparison with the previously recorded particle-microscopic image and is otherwise substantially the same as the latter. However, if the two images recorded with different focus settings are recorded using a particle beam that does not pass through the objective lens centrally, the two images differ not only in respect of image sharpness but also in respect of the relative position thereof. The change in the focus setting leads to the second image being displaced or offset relative to the first image. Therefore, what is known as a “wobble method” is performed for the purpose of adjusting the particle beam, within the scope of which the focus setting is changed periodically while images are recorded continuously. A user observes the recorded images, which move back and forth in the case of an improperly adjusted beam, and changes the excitation of the deflection device or deflection devices until the resultant images are all substantially stationary. This is a manual process that involves a certain amount of experience and is therefore also time-consuming.

In addition to the manual wobble method described above, automated methods are also known, which record a multiplicity of images in the case of pairwise different settings of the focus setting and the excitation of the deflection device. An optimum setting of the excitation of the deflection device is computed and set on the basis of an analysis of the multiplicity of recorded images. Then, the desired high-quality particle-microscopic images of the object are recorded using this setting. By way of example, such methods are known from U.S. Pat. No. 6,864,493 B2, US 2012 / 0 138 793 A1, U.S. Pat. Nos. 8,766,183 B2 and 7,705,300 B2.

In general, the manual or automated methods described above are electrostatic-based or magnetic-based automated adjustment methods. This type of adjustment can be valuable and can also allow fine adjustment of the system.

On the other hand, an electrostatic and/or magnetic adjustment may also only be as good as is allowed by the mechanical adjustment on which it is based, so to speak. First of all, specifically, it is the case that the system components or particle-optical components first are mechanically arranged or aligned with one another as precisely as possible. This mechanical adjustment then forms the starting point for the further electrostatic and/or magnetic adjustment. By way of example, the beam generator, various stops, lenses and detectors are precisely arranged or aligned with one another. This alignment and setting is normally carried out manually, and a multiplicity of adjusting screws and fixing screws are used for this purpose. In the region of the stops, it is also known to displace the stops by way of a piezo-element or stepper motor. Mechanical adjustment of the lenses, and for example of the magnetic lenses, can be particularly difficult. Such adjustment can take a relatively long time and are normally performed while observing an electron-microscopic image at the same time. Screws on the exterior of the particle beam microscope or particle beam column or the housing thereof are adjusted in order to adjust the magnetic lenses. The magnetic lenses are normally adjusted and subsequently fixed during commissioning of the particle beam column on site, after which this adjustment normally remains unchanged. Readjustment can be difficult and can be undesirable due to downtimes of the particle beam column, which may be embedded in a larger overall system or production. Mechanical adjustment of magnetic lenses can be difficult because it is generally not possible to determine precisely the magnetic field generated in the lens due to the geometric dimensions of such a magnetic lens. In other words, the magnetic field of magnetic lenses manufactured identically within the scope of the manufacturing accuracy may feasibly be measurably different from one another, which is why an individual lens adjustment is used.

An electrically driveable mechanical lens adjustment, for example of large magnetic lenses, is described in German patent application DE 10 2022 114 098.9 A1, which has not yet been laid open at the priority date of this patent application and the disclosure of which is incorporated in full into the present patent application by reference. Adjustment algorithms for automated mechanical adjustment of particle beam columns are not yet known.

US 2013/03220210 A1 discloses automated electrical adjustment for a single beam column.

U.S. Pat. No. 7,705,300 B2 discloses automated electrical adjustment in the event that a particle beam does not impinge vertically on a sample. Methods for setting a stigmator, an objective lens and a deflector are disclosed.

DE 10 2017 220 398 B3 discloses a beam adjustment device that is put into different settings. Multiple images are recorded in different settings and an optimized setting of both the beam adjustment device and an objective lens excitation value is ascertained therefrom. The beam adjustment device may be an electrostatic beam deflector or a magnetic beam deflector. The beam adjustment device may also comprise a stop that is able to be displaced. The setting of the beam adjustment device may also comprise setting a position of the stop in at least one direction. Further details regarding a mechanical adjustment or a mechanical adjustment method are not disclosed in that document.

### SUMMARY

The disclosure seeks to improve the adjustment of a particle beam column as a whole. The adjustment is intended to be able to be carried out for example relatively rapidly and possibly relatively precisely.

The present disclosure involves an electrically driveable mechanical adjustment mechanism or positioning mechanism for a multiplicity of particle-optical components of a particle beam column. This also applies for example to the abovementioned electrically driveable mechanical adjustment units for magnetic lenses. Therefore, it is possible and desirable, in addition to already known electrostatic and/or magnetic adjustment methods, to skilfully automate the previously manual, mechanical adjustment of the particle-optical components. This automated mechanical adjustment relates to various subregions of the particle beam column, which may in general be automatically mechanically adjusted independently of one another. In addition, these partial adjustment aspects may be combined into a sequence for a meaningful overall mechanical adjustment. Of course, an electrostatic and/or magnetic adjustment that is already known per se may be carried out for example automatically after the mechanical adjustment according to the disclosure has taken place or else between the individual sections of the mechanical adjustment for certain subregions.

According to a first aspect of the disclosure, the disclosure relates to a method for the mechanical adjustment of a particle beam column, wherein the particle beam column has the following:
a beam generator having a particle source and having an extractor stop for generating a particle beam containing charged particles,
an anode stop,
a condenser lens system for bundling the particle beam,
a condenser stop for shaping the particle beam,
a first deflection unit for deflecting the particle beam, which is arranged between the anode stop and the condenser stop in relation to the particle-optical beam path,
an objective lens system for focusing the particle beam onto an object, wherein interaction particles arise when the particle beam interacts with the object,
a detection system for detecting the interaction particles, wherein the detection system is arranged for example within the particle beam column and for example so as to run annularly around the optical axis of the particle beam column, and
a controller for controlling the particle beam column,
wherein the method, in an operating mode in which the particle beam column is operated with the condenser lens system switched off and with the objective lens system switched off, comprises the following steps:
for a plurality K of different positions Pij:
   a1) positioning the beam generator in a position Pij by way of an electrically driveable mechanical beam head adjustment mechanism;
   b1) scanning the condenser stop with the particle beam by way of the first deflection unit and generating a raster image Sij of the condenser stop by way of the detection system;
   c1) analysing the raster image Sij with regard to the condenser aperture imaged thereon;
d1) determining a best raster image Sbest based on the analysis or on the analyses according to step c1); and
e1) positioning the beam generator, by way of the electrically driveable mechanical beam head adjustment mechanism, in a position Pbest in which the best raster image Sbest was generated.

By way of the automated mechanical adjustment method indicated above, a position of the beam generator can be set relative to a position of the anode stop and a position of the condenser stop. A position of the anode stop relative to the position of the condenser stop may be fixed in this case; another exemplary embodiment will be discussed in more detail below. The condenser stop is a stop for shaping the particle beam. It thus can cut the particle beam that passes through it. The condenser stop may in this case comprise a single aperture, but it may also have a multiplicity of differently sized condenser apertures. A single condenser aperture is normally used in a condenser lens system having two condenser lenses, while the dual condenser lens system allows continuous setting of the beam current. A condenser stop having a plurality of condenser apertures is normally used in combination with a single condenser. In this case, for example, the generated particle beam can be displaced parallel or laterally by way of electrostatic and/or magnetic deflection elements, such that it passes through one of the differently sized openings in the condenser stop in a targeted manner. This can help make it possible to select a beam current for the particle beam in stepped fashion.

The beam generator can comprise at least one particle source and an extractor stop for generating a particle beam containing charged particles. It may however, of course, also have a suppressor electrode. The beam generator is often referred to as a “gunhead” and often forms a separate assembly. According to the disclosure, the beam generator can be displaced or is able to be positioned in a multiplicity of different positions Pij by way of an electrically driveable mechanical beam head adjustment mechanism. The electrically driveable mechanical beam head adjustment mechanism may in this case be driven by way of the controller or a control signal generated by the controller of the particle beam column. The electrically driveable mechanical beam head adjustment mechanism may for example comprise one or more actuators. By way of example, it is possible here to move the beam generator within a plane. For example, it is possible to move or position the beam generator in two mutually independent, for example orthogonal, directions x, y. This two-dimensional nature is indicated by the two indices ij in relation to the moved-to positions Pij. It is possible for example to provide an actuator for each of the directions x and y. However, it is also possible to provide a total of for example four actuators, wherein two actuators are provided for each direction x and y, respectively. In this case, actuators that are associated with one another and are to be assigned to the same direction are synchronized and driven in opposition to one another by the controller.

In the method described above, raster images Sij or shadow images of the at least one condenser aperture of the condenser stop are generated in general for different positions Pij. Depending on the relative position of the beam generator, on the one hand, and the system consisting of anode stop and condenser stop, on the other hand, the raster images Sij depict a different shape of the condenser aperture imaged thereon, on the one hand, and the raster images Sij also differ in terms of their intensity, on the other hand. These differences come about due to the different cutting of the originally generated particle beam by the sequence of stops (anode stop and condenser stop). By definition, the best raster image S_{best} is recorded here in the position P_{best} and, in this position P_{best}, the beam generator is then also positioned by way of the electrically driveable mechanical beam head adjustment mechanism.

The analysis of the raster images Sij with regard to the at least one condenser aperture imaged thereon may be carried out automatically by way of image evaluation algorithms. For example, in the case of multiple apertures imaged on the raster image, a reference aperture may first be identified; this may be for example an opening arranged centrally in the condenser stop. For example, the intensity in the associated raster image region may then be determined, for example be summed.

The detection system may be designed in various ways or the detection system may be arranged at various positions with respect to the particle beam column. It is possible for example for the detection system to be arranged within the particle beam column and for example in the form of a ring detector. However, it is also possible to use a chamber detector for the detection.

It is generally desirable to use a flat, unstructured sample for the adjustment described above, so that no artefacts due to material contrast or topography contrast occur in the shadow images. It is also generally desirable to set a contrast of the detector that is used to be so high that image noise is visible in the recorded or computed raster image. The high contrast can help facilitate image analysis and thus can help make it easier to ascertain the best raster image S_{best}.

According to an embodiment of the disclosure, the best raster image S_{best} is ascertained according to the criterion of greatest intensity. The intensity is at a maximum for best alignment and, in this case, in the case of a circular opening in the condenser stop, a round white circle may be identified on the raster image S_{best}. In the position P_{best}, optimally each pixel in the image of the condenser aperture is saturated.

According to an embodiment of the disclosure, the method described above is performed in two stages. In this case, the method is performed in the first stage in method step a1) with a first step width over a first region, and the method is performed in the second stage in method step a1) over a second region, which is smaller than the first region, with a second step width that is finer than the first step width. In the first stage, a first relatively rough ascertainment of the best position P_{best1} of the first stage is thus carried out. This is able to be found relatively quickly due to the selected relatively large step width, for example around 500 μm step width. Next, in the second stage, a finer scan is carried out around the found position P_{best1} from the first stage in order to ascertain a position P_{best2} of the second stage. The second region thus in this case contains the position P_{best1} from the first stage, which is for example located in the centre of the second region. It is thereby possible to ascertain the overall best position P_{best} for the beam generator very quickly and with great accuracy and to move to this position.

According to an embodiment of the disclosure, in method step a1), the beam generator is positioned in two mutually independent, for example orthogonal, directions x, y. This Cartesian system is typical in manufacturing.

According to an embodiment of the disclosure, the beam generator is displaced between different positions with a constant step width, for example with a constant step width in each direction. It is possible here for the constant step width to be the same in each direction, for example in the directions x and y. However, it is also possible for a different constant step width to be selected for each of the directions x and y.

According to an embodiment of the disclosure, an order in which the positions Pij are moved to is defined beforehand, and all of the positions Pij are also actually moved to. By way of example, this order may be defined in a program code. If all positions Pij are actually moved to, this means that the position P_{best} is also actually moved to in the process. This applies at least if the smallest possible step width in both directions is also selected for at least one stage of the method. However, this approach may not be as fast as the alternative approach described below:

According to an embodiment of the disclosure, the raster images Sij are analysed after each movement or displacement step and before the next movement or displacement step and a step width and/or a step direction for the respective next movement or displacement step is ascertained adaptively based on the result of the analysis. By way of example, it is possible to ascertain the global maximum for the best image S_{best} in the associated position of the beam generator P_{best} using a gradient-based search algorithm. Gradient-based image evaluation algorithms are already known or are available in general. The step width may likewise be selected adaptively and depends for example on the ascertained intensity. If the intensity of the imaged condenser aperture is still low, then a relatively large step width may initially be used for the next step or steps. If the intensity is already very high, then it is desirable to reduce the step width or to use a small step width for the next movement or displacement steps. By way of example, a step width of 500 μm may be used in the case of an intensity that is still low, and a step width of only 10 μm may be used in the case of an intensity that is already very high. This makes it possible to find the best position P_{best} for the beam generator quickly.

According to an embodiment of the disclosure, the best position of the beam generator is considered to have been reached and is defined as best position in the presence of at least one final termination criterion for a raster image. The final termination criterion may be defined for example by a minimum intensity that is defined beforehand.

According to an embodiment of the disclosure, the method furthermore comprises the following method steps:
varying a z-position of the particle source in the direction of the particle-optical axis Z by way of an electrically driveable mechanical source adjustment mechanism, and thus the distance of the particle source from the extractor stop,
measuring an extractor current in the respective z-position,
determining the best z-position based on the measured extractor currents, and
positioning the particle source in the best z-position by way of the electrically driveable mechanical source adjustment mechanism. The electrically driveable mechanical source adjustment mechanism may in this case again be controlled by way of the controller. This displacement of the particle source relative to the extractor stop may be used to compensate for any non-uniform radiation pattern of the particle source. The radiation intensity may then for example be substantially uniform or homogeneous for any angle.

According to an aspect of the disclosure, the disclosure relates to a method for the mechanical adjustment of a particle beam column, wherein the particle beam column has the following:
a beam generator having a particle source and having an extractor stop for generating a particle beam containing charged particles,
an anode stop,
a condenser lens system for bundling the particle beam,
a condenser stop for shaping the particle beam,
a first deflection unit for deflecting the particle beam, wherein the first deflection unit is arranged between the anode stop and the condenser stop in relation to the particle-optical beam path,
an objective lens system for focusing the particle beam onto an object, wherein interaction particles arise when the particle beam interacts with the object,
a detection system for detecting the interaction particles, wherein the detection system is arranged for example within the particle beam column and for example so as to run annularly around the optical axis of the particle beam column, and
a controller for controlling the particle beam column,
wherein the method, in an operating mode in which the particle beam column is operated substantially with the condenser lens system switched off and substantially with the objective lens system switched off, comprises the following steps:
for a plurality of anode stop positions APij and a plurality of condenser stop positions PBkl:
   a2) positioning the anode stop in an anode stop position APij by way of an electrically driveable mechanical anode stop adjustment mechanism;
   b2) positioning the condenser stop in a condenser stop position BPkl by way of an electrically driveable mechanical condenser stop adjustment mechanism;
   c2) scanning the condenser stop with the particle beam by way of the first deflection mechanism and generating a raster image Sijkl of the condenser stop by way of the detection system;
   d2) analysing the raster image Sijkl with regard to the intensity and shape of the condenser aperture imaged thereon;
   e2) determining a best raster image Sbest based on the analyses according to step d2),
   f2) positioning the anode stop in a position APbest by way of the electrically driveable mechanical anode stop adjustment mechanism and positioning the condenser stop in a position BPbest by way of the electrically driveable mechanical condenser stop adjustment mechanism, wherein the positions APbest and BPbest correspond to the positions of the anode stop, respectively of the condenser stop, in which the best raster image Sbest was recorded.

In this variant embodiment of the disclosure, the particle source or emitter tip, the anode stop and the condenser stop may be aligned even more precisely with one another. In contrast to the first aspect of the disclosure, the second aspect of the disclosure has two setting options for changing the relative position of the anode stop relative to the particle source, on the one hand, and the position of the condenser stop relative to the position of the particle source, on the other hand, and selecting the optimum one. The anode stop is positionable in an anode stop position APij in this case by way of an electrically driveable mechanical anode stop adjustment mechanism. This may in turn be of single-part or multi-part design. The electrically driveable mechanical anode stop adjustment mechanism may be implemented for example in the form of one or two, for example two mutually opposing piezo-motors and/or stepper motors, which are each able to be driven by way of the controller of the particle beam column. The same applies to the implementation of the electrically driveable mechanical condenser stop adjustment mechanism, which may in turn be of single-part or multi-part design.

Due to the fact that the adjustment method according to the second aspect of the disclosure in general has two degrees of freedom (position of the anode stop and position of the condenser stop), it is desirable to perform the analysis of the raster image Sijkl with regard to two parameters. In the described embodiment, this involves an analysis of the raster image Sijkl with regard to intensity, on the one hand, and shape, on the other hand, of the condenser stop or opening imaged in the raster images. The four indices ijkl in this case assign each raster image to a position of the anode stop (coordinates i and j), on the one hand, and to a position of the condenser stop (coordinates k and l), on the other hand. In this variant embodiment of the disclosure as well, in general, a shadow image is again recorded or a shadow image is generated or computed by scanning the sample.

The best raster image Sijkl may be ascertained for example according to the criterion of greatest intensity, on the one hand, and greatest accuracy of the imaged aperture, for example greatest roundness of the imaged aperture, on the other hand. In the case of a condenser stop having multiple condenser apertures, it is possible to select one of the openings for the image recording and to position the condenser stop accordingly in the particle-optical beam path. A central opening in the condenser stop can be selected here, but it is also theoretically possible to proceed differently.

According to an embodiment of the disclosure, the method furthermore comprises the following substeps:
g2) First of all, the positions APij of the anode stop are varied while keeping a fixed condenser stop position BPkl until the intensity of a generated raster image Sijkl exceeds a fixed threshold value. This creates for example a starting situation for the following method steps, in which at least a certain fraction of the generated particle beam passes through both the anode stop and the condenser stop.
h2) Next, positions BPkl of the condenser stop are varied while keeping a fixed position of the anode stop until the shape of the imaged condenser aperture has the greatest accuracy, for example the best roundness, wherein the fixed position of the anode stop in this method step is that position APij of the anode stop in which the threshold value was exceeded in step g2). In the course of this method step h2), the best possible homogeneous illumination of the condenser stop is thus achieved at a predefined anode stop position.
i2) Next, positions of the anode stop APij are varied again with a new fixed position of the condenser stop BPkl until the intensity of a generated raster image Sijkl reaches a maximum, wherein the new fixed position of the condenser stop is that position in which the greatest shape accuracy, for example the best roundness, was ascertained in step h2).
j2) Next, positions of the condenser stop are varied again with a new fixed position of the anode stop until the shape of the imaged condenser aperture has the greatest accuracy, for example the best roundness, wherein the new fixed position of the anode stop is that position of the anode stop in which the maximum intensity was reached in step i2).

According to an embodiment of the disclosure, steps g2), h2), i2) and j2) described above are carried out multiple times. The arrangement of the anode stop, on the one hand, and the condenser stop, on the other hand, thereby gradually and iteratively approaches the optimal arrangement of anode stop and condenser stop in relation to one another and in relation to the beam generator.

According to an embodiment of the disclosure, method steps g2), h2), i2) and j2) are repeated until a termination criterion for the intensity and/or the shape accuracy, for example the roundness, of the imaged condenser aperture is satisfied for a best raster image S_{best}. This termination criterion may be defined in advance in each case. However, it is also possible for the method to be used to optimize towards the overall greatest intensity and/or the overall greatest accuracy of the shape of the imaged condenser aperture.

According to an embodiment of the disclosure, in method step a2), the anode stop is positioned in two mutually independent, for example orthogonal, directions x, y and/or, in method step b2), the condenser stop is positioned in two mutually independent, for example orthogonal, directions x, y.

According to an embodiment of the disclosure, the anode stop is displaced between different positions with a constant step width, for example constant step width in each direction, and/or the condenser stop is displaced between different positions with a constant step width, for example with a constant step width in each direction. The step widths in each direction may in this case be identical, but they may also be of different sizes.

By way of example, the total movement range for each direction and stop may be 1 or 2 mm; a positional accuracy should be high, for example, accurate to at least 1 μm. These desired properties may in general be met with piezo-motors. These are more accurate than stepper motors. However, it would also be possible to use correspondingly improved motors to implement this variant embodiment.

According to a variant embodiment of the disclosure, the anode stop is displaced between different positions with an adaptive step width, wherein an adaptation of the step width is based on the ascertained intensity in at least one raster image Sijkl. In addition or as an alternative, the condenser stop may be displaced between different positions with an adaptive step width, wherein an adaptation of the step width is based on the ascertained shape accuracy, for example the roundness, of the imaged condenser stop in at least one raster image Sijkl.

In variant embodiments according to the second aspect of the disclosure as well, the raster images Sijkl are analysed automatically by way of image evaluation algorithms that are known.

When aligning the beam generator, the anode aperture and (at least one selected) condenser aperture, according to the first aspect of the disclosure, only the beam generator is displaceable. According to the second aspect of the disclosure, both the anode stop and the condenser stop are displaceable, while the beam generator is arranged in a fixed position. However, it is also conceivable to design all three components of the subsystem to be adjusted so as to be positionable and/or displaceable. In addition, it is conceivable, on the one hand, to design the beam generator and only one of the two stops so as to be positionable. In this case too, it is possible to align the three elements of the subsystem accurately in relation to one another. The method steps to be carried out for this purpose may be formulated in just the same way. In this case too, the optimization will be provided such that the relative position between the beam generator and the anode aperture is optimized with regard to intensity and that the relative position between the anode stop and the condenser stop is optimized with regard to the best homogeneous illumination of the condenser aperture.

In general, variant embodiments according to the first aspect of the disclosure and according to the second aspect of the disclosure may be combined in full or in part with one another, provided that this does not give rise to any technical contradictions.

According to a third aspect of the disclosure, the disclosure relates to a method for the mechanical adjustment of a particle beam column, wherein the particle beam column has the following:
a beam generator having a particle source and having an extractor stop for generating a particle beam containing charged particles,
an anode stop,
a condenser lens system for bundling the particle beam, having a first, for example magnetic condenser lens and having a second, for example magnetic condenser lens, wherein the first condenser lens is arranged above the second condenser lens in relation to the particle-optical beam path,
a condenser stop for shaping the particle beam, arranged between the first and the second condenser lens,
an objective lens system for focusing the particle beam onto an object, wherein interaction particles arise when the particle beam interacts with the object,
a scanning device for deflecting the particle beam and for scanning the object and arranged below the condenser stop in relation to the particle-optical beam path,
a detection system for detecting the interaction particles, wherein the detection system is arranged for example within the particle beam column and for example so as to run annularly around the optical axis of the particle beam column, and
a controller,
wherein the method, in an operating mode in which the particle beam column is operated for example with the objective lens system switched off, comprises the following steps:
3a) positioning the first condenser lens with a first pole shoe and a second pole shoe in a condenser lens position K1Pijkl;
3b) exciting the first condenser lens with a first weak excitation strength and, during this, wobbling the condenser lens excitation or wobbling an acceleration voltage of the beam generator;
3c) generating multiple raster images by way of the detection system during the wobbling, wherein, for each raster image, the particle beam is raster-scanned over the object by way of the scanning device;
3d) determining a displacement of the emission spot imaged in the raster images during the wobbling;
3e) repeating, for example repeating multiple times, steps 3b) to 3d) and, during this, varying the position of only the first pole shoe of the condenser lens by way of an electrically driveable mechanical first pole shoe adjustment mechanism;
3f) ascertaining a position of the first pole shoe in which the displacement of the emission spot in the raster images is reduced, for example at a minimum; and
3g) positioning only the first pole shoe in the position ascertained in step 3f) by way of the electrically driveable mechanical first pole shoe adjustment mechanism.

According to this third aspect of the disclosure, a double condenser thus can be mechanically adjusted. Using the method described above, the first, for example magnetic condenser lens of the double condenser can be adjusted with regard to a particle-optical tilt of the first condenser lens such that, after this tilt has been eliminated, a particle beam or electron beam passes through the centre of the first, for example magnetic condenser lens and the first condenser lens focuses the particle beam into the centre of the condenser aperture, which represents the beam-limiting stop. The particle beam column may in this case be identical to the particle beam column according to the first or second aspect of the disclosure, even if other components of the particle beam column are sometimes explicitly mentioned in the method described above with regard to the third aspect of the disclosure. This is because the automated mechanical adjustment of the double condenser lens system is in general independent of the automated adjustment of the beam head. In general, however, both automated adjustments of subsystems of the particle beam column may of course be performed successively on the same particle beam column.

According to the third aspect of the disclosure, a scanning device can be used to deflect the particle beam and scan the object and is arranged below the condenser stop in relation to the particle-optical beam path. This may involve a second or third deflection unit that is already installed in existing particle beam columns by way of electrostatic and/or magnetic deflectors. However, this can involve a system of deflection coils that are arranged in the region of the objective lens and that are also used to scan the object in normal standard operation of the particle beam column.

According to method step 3a), the first condenser lens is positioned with a first pole shoe and a second pole shoe in a condenser lens position K1Pijkl. In this case, 1 indicates the reference to the first condenser lens, P indicates the position and the four indices ijkl are to be assigned, as one half, to the position of the first pole shoe and, as the other half, to the position of the second pole shoe. At least one of the pole shoes is able to be displaced or positioned in a targeted manner by way of an electrically driveable mechanical first pole shoe adjustment mechanism. This electrically driveable mechanical first pole shoe adjustment mechanism may in this case be of single-part or multi-part design. By way of example, it may comprise a total of four actuators in order to be able to move the first pole shoe in one plane in two directions as desired. In this case, two actuators, arranged for example opposite one another, are driven identically in opposition by the controller of the particle beam column.

The displacement or positioning of the first pole shoe brings about a relative change in the position of the two pole shoes of the first condenser lens in relation to one another. Such a relative displacement of the two pole shoes in relation to one another, in particle-optical terms, has substantially the same effect as tilting the condenser lens with both pole shoes as a whole. Method steps 3a) to 3g) are thus used to correct a tilt of the first condenser lens.

Any tilt of the first condenser lens is in this case made visible either by wobbling the condenser lens excitation or by wobbling an acceleration voltage of the beam generator in the raster images recorded during the wobbling. Wobbling has already been described in the introductory part of the description. Wobbling is a periodic variation in the condenser lens excitation or a periodic variation in the acceleration voltage of the beam generator. In the event of tilting, a displacement is visible in the raster images with regard to the imaged emission spot. If this displacement is minimized, then the tilt of the condenser lens can be minimized as a whole as well. Image evaluation algorithms that are already known per se may again be used for image evaluation.

According to an embodiment of the disclosure, not only is any tilting of the condenser lens in relation to the particle-optical axis of the particle beam column corrected, but also a position of the focal point or displacement is corrected. For this purpose, according to an embodiment of the disclosure, the following may be carried out:
3h) Increasing the excitation of the first condenser lens and thereby generating multiple raster images by way of the detection system during the increasing of the excitation, wherein, for each raster image, the particle beam is raster-scanned over the object by way of the scanning device, and determining an intensity of the raster images, wherein the excitation of the condenser lens is increased until the intensity in one of the raster images falls below a threshold value. This threshold value may be fallen below owing to the fact that the focal length of the first condenser lens is shortened due to the increasingly stronger excitation and the focal point, in the event of misalignment, comes to lie close to the condenser stop plane, and thus intensity is cut off or becomes lower. Again, the intensity in the raster images is ascertained using automated image evaluation algorithms that are already known per se.
3i) Displacing the condenser lens as a whole, wherein the first pole shoe is displaced by way of the electrically driveable mechanical first pole shoe adjustment mechanism and wherein the second pole shoe is displaced by way of the electrically driveable mechanical second pole shoe adjustment mechanism. This electrically driveable mechanical second pole shoe adjustment mechanism may in turn be of single-part or multi-part design. By way of example, it may have two actuators or else four actuators. In the case of four actuators, it is optional for in each case two actuators to be designed in pairs for a displacement in one direction and to be driven synchronously in opposition by the controller of the particle beam column. In this respect, the same applies to the electrically driveable mechanical second pole shoe adjustment mechanism as has already been stated above for the electrically driveable mechanical first pole shoe adjustment mechanism. Displacing the condenser lens as a whole then means that both pole shoes are displaced both in the same direction and by the same magnitude. In this case, the two step widths may be identical for both pole shoe displacements, but the step widths may also be different. The decisive factor is that the displacements are of the same magnitude overall. This maintains the current tilt of the first condenser lens, and only the position of the focal point of the first condenser lens is changed.
3j) Repeating, for example repeating multiple times, steps 3h) to 3i). This makes it possible to iteratively improve the position of the focal point or to reduce a distance of the intensity spot/focus spot from the image centre.
3k) Ascertaining a position of the first condenser lens in which the intensity determined in step 3h) is at a maximum or exceeds a threshold value. This maximum intensity or the exceeding of a threshold value for the intensity may be ascertained directly or indirectly; therefore, substantially the same termination criteria may also be used for the value of the intensity itself as a termination criterion. By way of example, a position in which a threshold value of a position deviation of the focus spot from the image centre is fallen below substantially corresponds to a position of sufficiently high or maximum intensity. At this maximum intensity, the focal point of the first condenser lens is within the condenser aperture, such as in the centre.
3l) Positioning the condenser lens as a whole in the condenser lens position K1Pijkl ascertained in step 3k), wherein the first pole shoe is displaced by way of the electrically driveable mechanical first pole shoe adjustment mechanism and wherein the second pole shoe is displaced by way of the electrically driveable mechanical second pole shoe adjustment mechanism.

According to an embodiment of the disclosure, a sequence of method steps 3a) to 3l) is carried out repeatedly, for example carried out repeatedly multiple times. In this way, the tilt and displacement of the first condenser lens can be adjusted or optimized alternately with respect to the optimum alignment or position.

According to an embodiment of the disclosure, the repetition of the sequence of method steps 3a) to 3l) ends when the displacement ascertained in step 3f) is minimized globally and/or when the intensity ascertained in step 3k) is maximized globally. In this case, both the tilt and the displacement can be optimally mechanically and automatically corrected.

According to an embodiment of the disclosure, the second condenser lens is mechanically adjusted following a mechanical adjustment of the first condenser lens, for example wherein the first condenser lens is switched off. This mechanical adjustment of the second condenser lens may also be performed automatically. The second condenser lens may also be automatically mechanically adjusted with regard to a tilt and with regard to a displacement. As already explained with regard to the adjustment of the first condenser lens, it is also the case with the adjustment of the second condenser lens that it does not have to be tilted/counter-tilted itself in order to correct a tilt, but rather there is again a return to the concept whereby, with regard to the particle-optical imaging, tilting the lens is substantially equivalent to displacing the two pole shoes of the condenser lens in relation to one another. For this purpose, corresponding electrically driveable mechanical pole shoe adjustment mechanism may again be provided for the second condenser lens. It is possible for example for the first pole shoe to be able to be displaced by way of an electrically driveable mechanical first pole shoe adjustment mechanism of the second condenser lens and for the second pole shoe to be able to be displaced by way of an electrically driveable mechanical second pole shoe adjustment mechanism for the second condenser lens. The electrically driveable mechanical first or second pole shoe adjustment mechanism for the second condenser lens may again likewise be of single-part or multi-part design. They may each comprise one or two or four actuators. These may be arranged for example in Cartesian fashion and driven identically in opposition and in synchronicity in each direction by way of the controller of the particle beam column.

According to an embodiment of the disclosure, tilt correction of the second condenser lens with a first pole shoe and a second pole shoe takes place as follows:
3m) Positioning the second condenser lens with the first pole shoe and the second pole shoe in a condenser lens position K2Pijkl;
3n) exciting the second condenser lens with a first weak excitation strength and, during this, wobbling the condenser lens excitation or wobbling an acceleration voltage of the beam generator;
3o) recording multiple raster images by way of the detection system during the wobbling, wherein, for each raster image, the particle beam is raster-scanned over the object by way of the scanning device;
3p) determining a displacement of the emission spot imaged in the raster images during the wobbling;
3q) repeating, for example repeating multiple times, steps 3n) to 3p) and, during this, varying the position of only the first pole shoe of the second condenser lens by way of an electrically driveable mechanical first pole shoe adjustment mechanism of the second condenser lens;
3r) ascertaining a position of the first pole shoe of the second condenser lens in which the displacement of the emission spot in the raster images is reduced, for example at a minimum; and
3s) positioning only the first pole shoe of the second condenser lens in the position ascertained in step 3r) by way of the electrically driveable mechanical first pole shoe adjustment mechanism of the second condenser lens.

Furthermore, according to an embodiment of the disclosure, a displacement of the second condenser lens as a whole in the particle-optical beam path may be mechanically adjusted as follows:
3t) exciting the second condenser lens with a second excitation strength greater than the first excitation strength, recording an associated raster image by way of the detection system and ascertaining a position deviation of the focus spot with respect to the optical axis;
3u) displacing the second condenser lens as a whole, wherein the first pole shoe is displaced by way of the electrically driveable mechanical first pole shoe adjustment mechanism of the second condenser lens and wherein the second pole shoe is displaced by way of the electrically driveable mechanical second pole shoe adjustment mechanism of the second condenser lens;
3v) repeating, for example repeating multiple times, steps 3t) to 3u);
3w) ascertaining a position of the second condenser lens in which the position deviation ascertained in step 3u) is at a minimum; and
3x) positioning the second condenser lens as a whole in the condenser lens position K2Pijkl ascertained in step 3w), wherein the first pole shoe is displaced by way of the electrically driveable mechanical first pole shoe adjustment mechanism of the second condenser lens and wherein the second pole shoe is displaced by way of the electrically driveable mechanical second pole shoe adjustment mechanism of the second condenser lens.

According to an embodiment of the disclosure, a sequence of method steps 3m) to 3x) is carried out repeatedly, for example carried out repeatedly multiple times. This again makes it possible to iteratively achieve a mechanical adjustment of the second magnetic condenser lens that is as optimal as possible.

Furthermore, after the adjustment has been carried out, that is to say possibly after the iterations of the multiplicity of adjustment steps described above, a final checking step or a complete test run for the adjustment may be carried out, in which all control parameters identified as sufficiently best or optimum control parameters are checked again.

The following orders of magnitude and considerations may apply both for the mechanical adjustment of the first condenser lens and for the mechanical adjustment of the second condenser lens. One or two actuators, for example piezo-motors or stepper motors, or else combinations thereof, may be provided for each pole shoe. Typical movement ranges in one direction for a pole shoe are for example 1.5 mm, 2.0 mm, 2.5 mm or 3.0 mm. The accuracy of the movement range may in this case for example be between 5 μm and 20 μm. A displacement of the emission spot in the raster image, brought about by a tilt of one of the condenser lenses, may be quantified for example by the magnitude of the displacement relative to the diameter of the emission spot. A displacement of the two condenser lenses as a whole or even only one of their pole shoes may take place for example with step widths of a few μm, for example 10 μm, 15 μm or 20 μm. However, these are only indications that are not intended to restrict the disclosure.

According to a fourth aspect of the disclosure, the disclosure relates to a method for the mechanical adjustment of a particle beam column, wherein the particle beam column has the following:
a beam generator having a particle source and having an extractor stop for generating a particle beam containing charged particles,
an anode stop,
a condenser stop for shaping the particle beam, for example having a plurality of condenser apertures having different diameters,
an for example magnetic condenser lens for bundling the particle beam, wherein the condenser lens is arranged above the condenser stop in the particle-optical beam path,
an objective lens system for focusing the particle beam onto an object, wherein interaction particles arise when the particle beam interacts with the object,
a scanning device for deflecting the particle beam and for scanning the object and arranged below the condenser stop in relation to the particle-optical beam path,
a detection system for detecting the interaction particles, wherein the detection system is arranged for example within the particle beam column and for example so as to run annularly around the optical axis of the particle beam column, and
a controller for controlling the particle beam column,
wherein the method, in an operating mode in which the particle beam column is operated substantially with the objective lens system switched off, comprises the following steps:
4a) positioning the condenser lens in a condenser lens position KPij;
4b) exciting the condenser lens with a first weak excitation strength and, in the process, wobbling the condenser lens excitation or wobbling an acceleration voltage of the beam generator;
4c) generating multiple raster images by way of the detection system during the wobbling, wherein, for each raster image, the particle beam is raster-scanned over the object by way of the scanning device;
4d) determining a displacement of the emission spot imaged in the raster images during the wobbling;
4e) repeating, for example repeating multiple times, steps 4b) to 4d) and, during this, varying the position of the condenser lens by way of an electrically driveable mechanical condenser lens adjustment mechanism;
4f) ascertaining a position of the condenser lens in which the displacement of the emission spot in the raster images is reduced, for example at a minimum; and
4g) positioning the condenser lens in the position ascertained in step 4f) by way of the electrically driveable mechanical condenser lens adjustment mechanism.

The automated mechanical adjustment method according to the fourth aspect of the disclosure can be particularly suitable for particle beam columns having a single condenser. However, it is also possible to use the method for the mechanical adjustment of the first condenser in a double condenser system, provided that the first condenser in the double condenser is intended to be mechanically adjusted only with regard to displacement. In the case of a single condenser, mechanical adjustment can be easier as a whole than with a double condenser. For example, it has been found in practice that a tilt of the single condenser is practically irrelevant for the adjustment, which is why it is sufficient in the vast majority of cases to displace only the first condenser as a whole. Technically, an electrically driveable mechanical condenser lens adjustment mechanism is again provided. This in turn can be intended to allow a displacement within one plane, and thus in two mutually independent directions. One or two actuators for a position change may again be provided for each direction, as has already been explained in detail in connection with the third aspect of the disclosure. The electrically driveable mechanical condenser lens adjustment mechanism is also again driven by way of the controller of the particle beam column. The particle beam column itself may in turn—possibly apart from the specific design of the condenser—be identical to the particle beam columns as were described in connection with the first, second and third aspect of the disclosure.

According to a fifth aspect of the disclosure, the disclosure relates to a method for the mechanical adjustment of a particle beam column, wherein the particle beam column has the following:
a beam generator having a particle source and having an extractor stop for generating a particle beam containing charged particles,
an anode stop,
a condenser stop for shaping the particle beam,
a condenser lens system having at least one, for example magnetic condenser lens for bundling the particle beam, wherein the at least one condenser lens of the condenser lens system is arranged above the condenser stop in the particle-optical beam path,
an objective lens system for focusing the particle beam onto an object, wherein interaction particles arise when the particle beam interacts with the object,
a scanning device for deflecting the particle beam and for scanning the object and arranged below the condenser stop in relation to the particle-optical beam path,
a detection system for detecting the interaction particles and arranged within the particle beam column between the condenser lens system and the objective lens system and so as to run, for example run annularly, around the optical axis of the particle beam column, wherein the detection system has a first detector having a first detector hole and wherein the detection system has a second detector having a second detector hole for the passage of the particle beam and wherein the first detector is arranged above the second detector in relation to the particle-optical beam path, and
a controller for the particle beam column,
wherein the method, in an operating mode in which the particle beam column is operated for example with the objective lens system switched off, comprises the following steps:
5a) positioning the first detector in a first position D1ij by way of a first electrically driveable mechanical detector adjustment mechanism;
5b) positioning the second detector in a second position D2ij by way of a second electrically driveable mechanical detector adjustment mechanism;
5c) scanning the object by way of the scanning device and generating a raster image by way of the first detector at a magnification that is chosen to be so small that the raster image images both the detector hole of the first detector as a first circle and the detector hole of the second detector as a second circle;
5d) determining the position of the first circle and determining the position of the second circle in the raster image;
5e) repeating steps 5c) and 5d) and, during this, varying the position D1ij of the first detector and/or varying the position D2ij of the second detector;
5f) ascertaining a position D1best of the first detector and ascertaining a position D2best of the second detector in which the first circle and the second circle are aligned concentrically with one another and/or in which both circles are arranged exactly in the image centre of the raster image; and
5g) positioning the first detector in the position D1best by way of the first electrically driveable mechanical detector adjustment mechanism and positioning the second detector in the position D2best by way of the second electrically driveable mechanical detector adjustment mechanism.

This fifth aspect of the disclosure therefore involves the automated mechanical adjustment of the detection system in relation to the particle-optical axis. The detection system itself is arranged within the particle beam column between the condenser lens system and the objective lens system so as to run annularly around the optical axis of the particle beam column. This type of detection system is also referred to as an “in-column” detection system. The first detector and the second detector are in this case arranged above one another and at a distance from one another and should each be adjusted centrally with the detector hole in relation to the particle-optical axis of the particle beam column.

According to an embodiment of the disclosure, the second detector is a secondary electron detector. It is located closer to the sample than the first detector. By way of example, the first detector is a backscattered electron detector. This arrangement is useful because the secondary electrons emerging from the sample normally have a lower energy and a wider angular distribution. This means that many of the secondary electrons are also actually able to be detected by way of the lower-lying second detector. On the other hand, backscattered electrons normally emerge from the sample or object with a higher energy and a much smaller angular spectrum. These backscattered electrons are therefore capable of passing through the detector hole of the second detector substantially unhindered, and they are detected only with the first detector.

To adjust the two detectors, a raster image is observed, which has been generated by way of the first detector (that is to say optionally the backscattered electron detector), specifically at a magnification that is chosen to be so small that the raster image images both the detector hole of the first detector as a first circle and the detector hole of the second detector as a second circle. The position of the first circle and the position of the second circle in the raster image are each determined. By varying the positions of the first detector and the second detector, it is possible to achieve a situation whereby the first circle and the second circle are aligned concentrically with one another and/or whereby both circles are arranged exactly in the image centre of the raster image.

Each of the two detectors in this case can be able to be displaced within a plane. This capability of displacement in two directions is indicated respectively by the two indices ij with respect to the position of the detectors. Each of the detectors is able to be displaced by way of an electrically driveable mechanical detector adjustment mechanism, wherein the signal underlying this displacement may in turn be generated by the controller of the particle beam column. Each of the electrically driveable mechanical detector adjustment mechanism may in turn again be of single-part or multi-part design. It is possible for one or else two actuators to be able to be used for each detector and for each displacement or adjustment direction. These actuators may again for example be stepper motors or else piezo-motors, which have greater accuracy with regard to positioning.

According to an embodiment of the disclosure, the method furthermore comprises the following step:
5h) generating sectional profiles of the raster images and automatically detecting the circle centres in the raster images, for example by applying gradient methods in the sectional profiles.

According to an embodiment of the disclosure, the method furthermore comprises the following step:
5i) increasing the image contrast before generating sectional profiles. This increase in contrast facilitates image evaluation.

The described method for the automated mechanical adjustment of the detection system may in turn be performed in combination with or after the automated adjustments of the other components of the particle beam column as described above. According to the fifth aspect of the disclosure, the particle beam column itself may in this case be identical to one or more particle beam columns according to the first, second, third and/or fourth aspect of the disclosure. In general, the method for the automated mechanical adjustment of the detection system may however also be used separately on its own.

According to a sixth aspect of the disclosure, the disclosure relates to a method for the mechanical adjustment of a particle beam column, wherein the particle beam column has the following:
a beam generator having a particle source and having an extractor stop for generating a particle beam containing charged particles,
an anode stop,
a condenser stop for shaping the particle beam,
a condenser lens system having at least one, for example magnetic condenser lens for bundling the particle beam, wherein a condenser lens of the condenser lens system is arranged above the condenser stop in the particle-optical beam path,
an objective lens system for focusing the particle beam onto an object, wherein interaction particles arise when the particle beam interacts with the object, and wherein the objective lens system has a magnetic lens and an electrostatic lens, wherein the magnetic lens is arranged above the electrostatic lens in the particle-optical beam path,
a scanning device for deflecting the particle beam and for scanning the object and arranged below the condenser stop in relation to the particle-optical beam path, and for example roughly level with the objective lens system,
a detection system for detecting the interaction particles and arranged for example within the particle beam column between the condenser lens system and the objective lens system and for example so as to run for example annularly around the optical axis of the particle beam column, and
a controller for the particle beam column,
wherein the method, in an operating mode in which the condenser lens system is switched on and in which the magnetic objective lens is switched on and focuses the particle beam onto the object, comprises the following steps:
6a) positioning the electrostatic objective lens in a first position OLij;
6b) exciting the electrostatic objective lens with a first excitation strength and, during this, wobbling the excitation of the electrostatic objective lens or wobbling an acceleration voltage of the beam generator;
6c) recording multiple raster images by way of the detection system during the wobbling, wherein, for each raster image, the particle beam is raster-scanned over the object by way of the scanning device;
6d) determining a displacement of the focus spot imaged in the raster images during the wobbling;
6e) repeating, for example repeating multiple times, steps 6b) to 6d) and, during this, varying the position of the electrostatic objective lens by way of an electrically driveable mechanical objective lens adjustment mechanism;
6f) ascertaining a position of the electrostatic objective lens in which the displacement of the focus spot in the raster images is reduced, for example at a minimum;
6g) positioning the electrostatic objective lens in the position ascertained in step 6f) by way of the electrically driveable mechanical objective lens adjustment mechanism.

The objective lens system of the described particle beam column comprises a magnetic lens and an electrostatic lens and thus operates in accordance with the Gemini-SEM lens principle. The electrostatic lens is also referred to as an end cap and provides an additional braking effect for the charged particles before the particle beam impinges on the sample. By way of example, it is thereby possible to achieve a deceleration of a few kV, for example 7 kV, 8 kV or 9 kV; however, this should not be understood as limiting the disclosure.

According to the sixth aspect of the disclosure, the electrostatic lens or the end cap of the objective lens system may then be automatically mechanically adjusted. It is expedient in this case for the particle beam already to enter the objective lens system centrally or on the optical axis using already known electrostatic and/or magnetic adjustment methods.

The automated mechanical adjustment method for the electrostatic objective lens is then again based on the fact that an imperfect adjustment or displacement of the electrostatic lens or of its field results in a displacement of the focus spot when incident on the object. If on the other hand the alignment of the electrostatic objective lens is central or ideal, then wobbling the excitation of the electrostatic objective lens or alternatively wobbling an acceleration voltage of the beam generator results only in overfocusing or underfocusing of the focus spot, but substantially no displacement.

The electrostatic objective lens itself may in turn be positioned or displaced by way of an electrically driveable mechanical objective lens adjustment mechanism. It is possible to position or displace the electrostatic objective lens in two for example mutually orthogonal directions x, y. In turn, the corresponding signals are provided by the controller of the particle beam column. The electrically driveable mechanical objective lens adjustment mechanism itself may in turn be of single-part or multi-part design. It may comprise one or two actuators, for example piezo-motors or stepper motors or combinations thereof, for each adjustment direction. In the case of two actuators, these can be driven synchronously and in opposition to one another by the controller.

According to an embodiment of the disclosure, the method furthermore comprises the following steps, which are carried out before method step 6a):
6h) Switching off the electrostatic objective lens;
6i) wobbling an excitation of a condenser lens in order to change an aperture angle of the particle beam; and
6j) adjusting the particle-optical beam path by way of electrostatic and/or magnetic deflectors such that the particle beam passes through the magnetic objective lens in a centred manner. In this adjustment step too, a displacement of the focus spot is again analysed. If no further displacement occurs, but rather only overfocusing or underfocusing, the adjustment of the particle beam with respect to the particle-optical axis or the axis of the magnetic objective lens is correct.

According to a seventh aspect of the disclosure, the disclosure relates to a method for the mechanical adjustment of a particle beam column, the method comprising the following steps:
7a) Mechanically adjusting the beam generator, anode stop and/or condenser stop relative to one another as described for example above according to the first and second aspect of the disclosure; and/or
7b) mechanically adjusting the condenser lens system as described above in connection with the third and fourth aspect of the disclosure in multiple variant embodiments; and/or
7c) mechanically adjusting the detection system as described above according to the fifth aspect of the disclosure in multiple variant embodiments; and/or
7d) mechanically adjusting the objective lens system as described above according to the sixth aspect of the disclosure in multiple embodiments.

It is optional in this case for the order of method steps 7a) to 7d) as described above to be strictly complied with. This compliance ensures an optimal adjustment, which also prevents unnecessary errors in the mechanical adjustment from propagating. Instead, each new “adjustment section” is started with the most optimum possible initial adjustment of the particle-optical components arranged further up in the particle-optical beam path. Of course, this does not rule out the possibility of further, for example electrostatic and/or magnetic adjustment steps taking place in the meantime or in advance of certain adjustment steps.

According to an aspect of the disclosure, the method furthermore comprises at least one of the steps listed below:
electrically adjusting the particle beam column by setting electrostatic and/or magnetic deflection elements;
setting an objective lens current;
setting the detection system with regard to brightness and/or contrast.

The automated mechanical adjustment of the particle beam column is therefore only one aspect of the overall adjustment, albeit of course a relevant aspect. For example, it is possible to drastically shorten the adjustment time as a whole and improve the adjustment accuracy with the aid of the automated mechanical adjustment according to the disclosure. The adjustment is able to be reproduced in a controlled manner and is easier to implement. In addition, a mechanical adjustment may also be performed “as desired” and, for example, may also be performed again, for example after a change of operating point. It is also possible to check the adjustment at regular intervals. It is also possible to perform the adjustment process again in the event of an apparent misalignment/malfunction of the particle beam column and/or in the event of changed environmental parameters and/or interference. Without the adjustment routines according to the disclosure, a readjustment or post-adjustment in the past was de facto not possible due to the associated time outlay and due to the experienced specialist personnel that are involved.

According to an embodiment of the disclosure, a reference object that is part of the particle beam column itself is used as an object for adjusting and/or qualifying the particle beam column. This means that the particle beam column is able to be adjusted and/or qualified independently of the properties of an external sample, an external sample stage, independently of other application-specific parameters and/or environmental parameters.

According to an embodiment of the disclosure, a shielding element that is electrically conductive and that is arranged downstream of the objective lens in the particle beam column in relation to the particle-optical beam path and onto which the particle beam is directed, or able to be directed, by way of a deflection device or scanning device is used as a reference object. The shielding element is configured to shield an electric field. Such a field to be shielded may be generated for example by charging an (external) sample by way of the particle beam of the particle beam column. It may therefore be expedient to shield the interior of the particle beam column, for example in the case of (external) samples that are electrically non-conductive or only slightly electrically conductive.

According to an embodiment of the disclosure, the shielding element has a mesh structure and multiple through-openings, wherein the mesh structure is structured as the reference object itself or is structured while the method is being carried out. The mesh structure thus only becomes the mesh structure as a result of the through-openings. The structuring on the mesh structure itself (that is to say not in the openings of the mesh structure) may be produced in various ways. It is possible, for example, to produce the structures directly by way of the particle beam column, possibly including a supplied process gas. As an alternative, it is also possible for the structures to have already been applied to the shielding element or its grid structure in a separate manufacturing step, for example before the assembly of the particle beam column, or during the mesh manufacturing process itself. By way of example, this may be done by vapour deposition and/or etching or by ion-beam or electron-beam lithography methods or by mechanical methods such as embossing.

According to an eighth aspect of the disclosure, the disclosure relates to a computer program product containing a program code that is able to be loaded into a controller of a particle beam column and, when the program code is executed, controls a particle beam column such that a method according to one of the aspects of the disclosure described above is carried out. The program code itself may in this case be executed in any programming language. The controller of the particle beam column itself may be of single-part or multi-part design. For example, it may be modular. The controller may for example have a processor into which the program code is able to be loaded.

According to a ninth aspect of the disclosure, the disclosure relates to a particle beam column that is configured to carry out the method as described above in connection with multiple aspects of the disclosure and in each case in multiple variant embodiments, wherein the particle beam column has a controller into which a computer program product as described above in connection with the eighth aspect of the disclosure is loaded. The particle beam column may thus comprise for example the numerous electrically driveable mechanical adjustment mechanism for the numerous particle-optical elements.

The various aspects and variant embodiments of the disclosure may be combined in full or in part, provided that no technical contradictions arise as a result.

### BRIEF DESCRIPTION OF THE DRAWINGS

The disclosure may be understood even better with reference to the accompanying figures, in which:

FIG. 1: schematically shows a particle beam column according to the disclosure having a double condenser;

FIG. 2: schematically shows a particle beam column according to the disclosure having a single condenser;

FIGS. 3A-3B: schematically show variants of an electrically driveable mechanical adjustment mechanism for a Cartesian adjustment;

FIGS. 4A-4C: schematically show a beam generator, which is able to be positioned by way of an electrically driveable mechanical beam head adjustment mechanism, as well as examples of raster images generated in different positions of the beam generator;

FIG. 5: schematically shows a method for the automated mechanical adjustment of a particle beam column with reference to the example of a beam generator adjustment;

FIGS. 6A-6B: schematically show a beam generator, an anode stop and a condenser stop, wherein the anode stop and the condenser stop are each able to be positioned relative to the beam generator by way of an electrically driveable mechanical anode stop adjustment mechanism or condenser stop adjustment mechanism, as well as examples of raster images generated in different positions of the stops;

FIG. 7: schematically shows a method for the automated mechanical adjustment of a particle beam column with reference to the example of an anode stop and condenser stop adjustment;

FIG. 8: schematically shows a further method for the automated mechanical adjustment of a particle beam column with reference to the example of an anode stop and condenser stop adjustment;

FIGS. 9A-9B: schematically shows a particle-optical beam path in the condenser lens system, or the light-optical analogue thereof;

FIG. 10: schematically shows a method for the automated mechanical adjustment of a particle beam column with reference to the example of an adjustment of the first condenser lens of a double condenser;

FIG. 11: schematically shows a method for the automated mechanical adjustment of a particle beam column with reference to the example of an adjustment of the second condenser lens of a double condenser;

FIG. 12: schematically shows a method for the automated mechanical adjustment of a particle beam column with reference to the example of an adjustment of a single condenser;

FIGS. 13A-13B: schematically show a low-magnification raster image with detector holes of two ring detectors imaged thereon, these being arranged above one another and spaced from one another and concentrically to the optical axis within the particle beam column, and an associated sectional profile;

FIG. 14: schematically shows a method for the automated mechanical adjustment of a detection system having two ring detectors arranged above one another and spaced from one another within the particle beam column;

FIG. 15: schematically shows a method for the automated mechanical adjustment of an electrostatic objective lens;

FIG. 16: schematically shows a device having a particle beam column for analysing and/or processing a sample;

FIG. 17: schematically shows a shielding element;

FIG. 18: schematically shows a shielding element with a structuring in the region of the mesh structure; and

FIG. 19: schematically shows examples of structuring of the mesh structure.

### DETAILED DESCRIPTION

The method for the mechanical adjustment of a particle beam column, the associated computer program product and the particle beam column are described in more detail below. By way of example, a scanning electron microscope is chosen as the particle beam column for the following description, but it is explicitly pointed out that the disclosure may also be used for other particle beam columns and for example also for ion beam columns, and not only for electron beam columns.

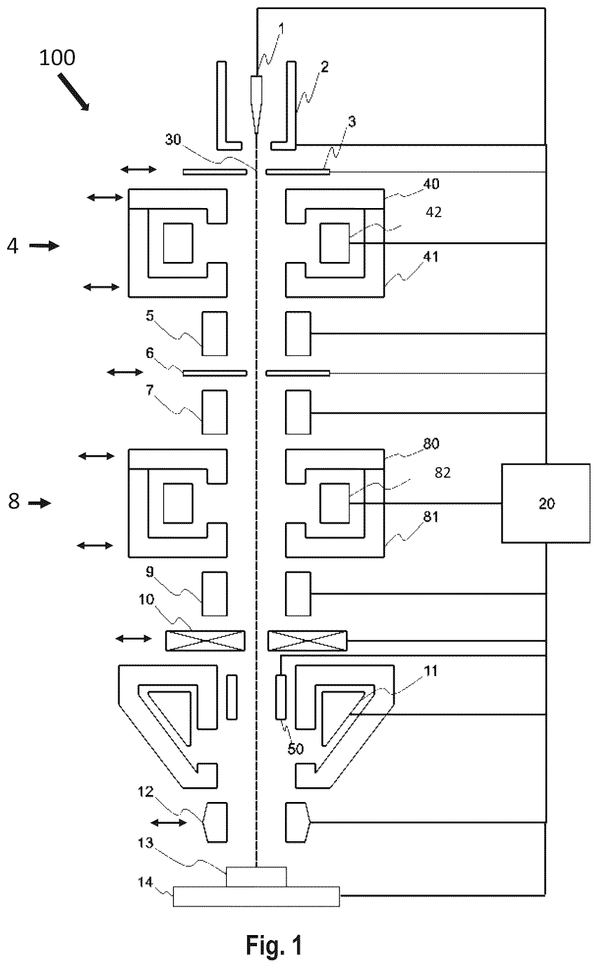

FIG. 1 schematically shows a particle beam column 100 according to the disclosure having a double condenser 4, 8. The particle beam column or the SEM 100 has a beam generator having an electron source 1, which is designed as a cathode. Moreover, the beam generator has a suppressor electrode 2 and an extractor stop (not illustrated). Furthermore, the SEM 100 is provided with an anode stop 3 that is mounted on one end of a beam guiding tube (not illustrated) of the SEM 100, for example is pressed onto the beam tube via a spacer ring. By way of example, the electron source 1 is designed as a thermal field emitter. However, the disclosure is not restricted to such an electron source 1. On the contrary, any electron source (or ion source) may be used in general.

Electrons emerging from the electron source form a primary electron beam. On account of a potential difference between the electron source 1 and the anode stop 3, the electrons are accelerated to a predefinable kinetic energy by way of a predefinable potential. In the exemplary embodiment illustrated here, the potential is 0.1 kV to 20 kV, for example 0.5 kV to 1 kV, for example 0.6 kV, in relation to a ground potential of a housing of a sample chamber (not illustrated). However, it could alternatively also be at ground potential. In addition, an acceleration voltage of 8 kV may be applied within the particle beam column, by which acceleration voltage the charge carriers are decelerated again before emerging from the column.

A double condenser lens system for bundling the electron beam, namely a first condenser lens 4 and a second condenser lens 8, is arranged along the particle-optical beam path. In this case, starting from the electron source 1 in the direction of an objective lens system 11, 12, there are arranged firstly the first condenser lens 4 and then the second condenser lens 8. In the illustrated exemplary embodiment, these are two magnetic lenses. A condenser stop or aperture stop 6 is arranged between the first condenser lens 4 and the second condenser lens 8. A first deflection unit 5 is arranged on a first side, facing the electron source 1, of the condenser stop 6. Furthermore, a second deflection unit 7 is arranged on a second side, facing the second condenser lens 8, of the condenser stop 6. By way of example, both the first deflection unit 5 and the second deflection unit 7 have electrostatic and/or magnetic units that are able to be set using a drive variable. In the example shown, the condenser stop 6 can be a stop having a single aperture. The condenser stop 6 is used to shape the particle beam or cuts the particle beam. It may therefore also be used to set the beam current of the particle beam. Owing to the design of the condenser lens system as a double condenser having the condenser lenses 4, 8, a beam current of the particle beam passing through the condenser stop 6 is able to be set continuously when the double condenser 4, 8 is driven accordingly.

The objective lens system has a magnetic objective lens 11 and an electrostatic objective lens 12, the latter also being referred to as an end cap. Providing the end cap 12 makes it possible to provide an electrostatic deceleration device in the lower region of the beam guiding tube (not illustrated) of the particle beam column 100. Electrons of the primary electron beam are thereby able to be decelerated to a desired energy used for the examination of a sample 13.

The particle beam column 100 or the scanning electron microscope 100 furthermore has a scanning device 50 by way of which the primary electron beam is able to be deflected and scanned over the object 13. In the process, the electrons of the primary electron beam interact with the object 13. The interaction gives rise to interaction particles, which are detected. For example, as interaction particles, electrons are emitted from the surface of the object 13—what are referred to as secondary electrons—or electrons of the primary electron beam are backscattered—what are referred to as backscattered electrons.

To detect the interaction particles, a detection system 10 is arranged in the beam guiding tube (not illustrated), which detection system for example has a first detector 10a and a second detector 10b. In this case, the first detector 10a is arranged on the source side along the particle-optical axis Z, while the second detector 10b is arranged on the object side along the optical axis Z in the beam guiding tube (not illustrated). The first detector 10a and the second detector 10b are arranged offset or spaced apart from another in the direction of the optical axis Z of the SEM 100. Both the first detector 10a and the second detector 10b have a respective through-hole 313, 311 through which the primary electron beam is able to pass. The first detector 10a and the second detector 10b are approximately at the potential of the anode stop 3 and of the beam guiding tube (not illustrated). The optical axis Z of the SEM runs through the respective through-openings 313, 311.

The second detector 10b serves mainly to detect secondary electrons. Upon emerging from the object 13, the secondary electrons initially have a low kinetic energy and random directions of movement. A suction field is used to accelerate the secondary electrons in the direction of the objective lens 11, 12. The secondary electrons enter the objective lens 11, 12 approximately parallel. The beam diameter of the beam of secondary electrons also remains small in the objective lens 11. The objective lens 11 then has a strong effect on the secondary electrons and produces a comparatively short focus of the secondary electrons with sufficiently steep angles with respect to the optical axis Z, such that the secondary electrons diverge far apart from one another downstream of the focus and impinge on the second detector 10b on the active area thereof. By contrast, only a small proportion of electrons that are backscattered at the object 13, that is to say backscattered electrons that have a relatively high kinetic energy in comparison with the secondary electrons upon emerging from the object 13, are captured by the second detector 10b. The high kinetic energy and the angles of the backscattered electrons with respect to the optical axis Z upon emerging from the object 13 have the effect that a beam waist, that is to say a beam region having a minimum diameter, of the backscattered electrons lies in the vicinity of the second detector 10b. A large portion of the backscattered electrons therefore passes through the through-opening of the second detector 10b. The first detector 10a therefore serves substantially to detect the backscattered electrons.

In a further embodiment of the SEM 100, the first detector 10a may additionally be designed to have a counter field grid (not illustrated). The counter field grid is arranged on that side of the first detector 10a facing the object 13. With respect to the potential of the beam guiding tube, the counter field grid has a negative potential such that only backscattered electrons with a high energy pass through the counter field grid to the first detector 10a. In addition or as an alternative, the second detector 10b may have a further counter field grid that has an analogous design to the abovementioned counter field grid of the first detector 10a and has an analogous function.

The detector signals generated by the first detector 10a and the second detector 10b are used to generate one or more images of the surface of the object 13. For this purpose, the first detector 10a and the second detector 10b are each connected to a controller 20. The detector signals are processed in the control unit 20 and may be displayed in the form of images, for example, on a monitor. The images themselves are generated or computed here in line with the raster principle. It is furthermore possible for image processing modules or image evaluation modules also to be integrated in the controller 10. By way of example, the controller 20 may have a processor into which is loaded a computer program product containing a program code that controls the SEM 100 such that the method according to the disclosure is carried out. This will be explained in more detail further below.

In addition to the detectors 10 shown explicitly in FIG. 1, the SEM 100 may also have further detectors, for example a chamber detector, which is arranged in the sample chamber. This is also generally suitable for imaging or generating raster images within the context of the disclosure.

The sample chamber (not illustrated) is under vacuum. To generate the vacuum, a pump (not illustrated) is arranged on the sample chamber. It is thus possible to achieve pressure ranges smaller than for example 10⁻³ hPa. To ensure these pressure ranges, the sample chamber is vacuum-sealed.

The controller 20 is connected to the components of the particle beam column 100 in a variety of ways in order to control it. FIG. 1 schematically shows certain relevant lines in this respect. It is thereby possible to set for example voltages and currents, and thus also generated lens fields or deflection fields. The same also applies to the cathode voltage, anode voltage, etc.

It is now relevant, within the scope of the present disclosure, that elements of the particle beam column 100 are also able to be supplied with control signals by way of which electrically driveable mechanical adjustment mechanism for certain components or component parts of the particle beam column 100 are able to be driven. These components are therefore movable and are able to be mechanically automatically adjusted. In the overview in FIG. 1, this fact is represented by the double-headed arrows on the left. By way of example, in the case of the particle beam column 100 in FIG. 1, the anode stop 3, an upper pole shoe 40 of the first condenser 4, a lower pole shoe 41 of the first condenser 4, the condenser stop 6, an upper pole shoe 80 of the second condenser lens 8, a lower pole shoe 81 of the second condenser lens 8, the detection system 10 having for example a first detector 10a and a second detector 10b as well as the electrostatic objective lens 12 or electrically driveable mechanical adjustment mechanism assigned thereto, may be driven by way of control signals. Further details regarding the electrically driveable mechanical adjustment mechanism for the mentioned components of the particle beam column are explained in even more detail below.

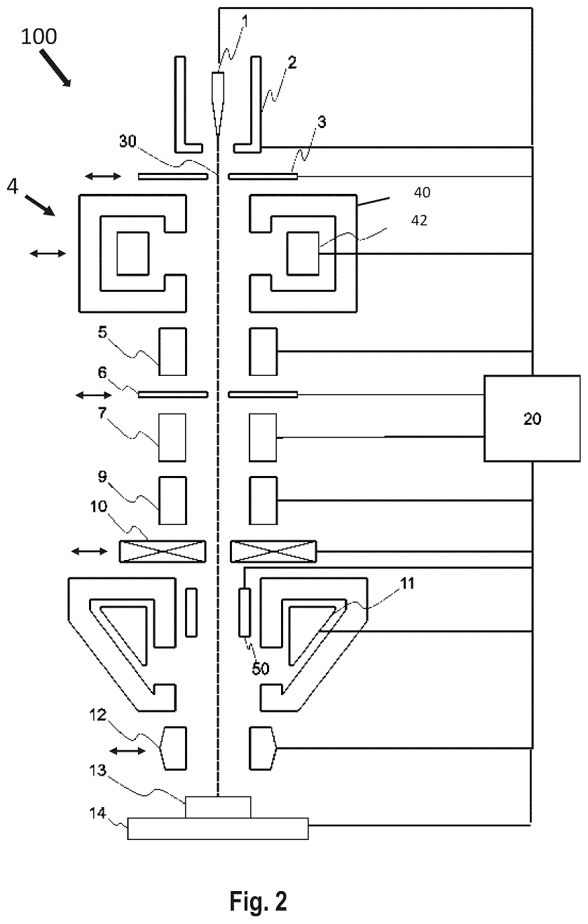

FIG. 2 shows a variant embodiment of a particle beam column 100 according to the disclosure. The illustration in FIG. 2 differs from the illustration according to FIG. 1 in that, instead of a double condenser 4, 8, only a single condenser 4 is provided. For this reason, the condenser stop 6 in FIG. 2 is designed as a stop with multiple holes. The respective current condenser aperture is selected in a manner known per se through appropriate driving of deflection units 5, 7 and/or through appropriate displacement of the condenser stop 6 in a plane orthogonal to the particle-optical axis Z. In addition, in this embodiment of the disclosure, the electrically driveable mechanical adjustment mechanism as already briefly described above are provided as well and are again indicated by the double-headed arrows on the left.

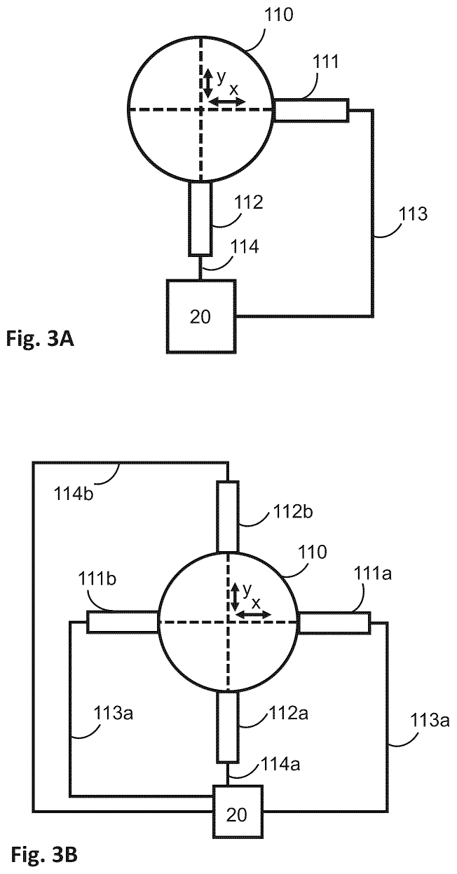

FIGS. 3A-3B schematically show variants of an electrically driveable mechanical adjustment mechanism for a Cartesian adjustment. A Cartesian adjustment in this case permits an adjustment in two mutually orthogonal directions x, y. The element 110 to be adjusted or positioned is illustrated only schematically in FIGS. 3A-3B. The element 110 to be adjusted, within the scope of this patent application, may involve those elements or components of the particle beam column 100 that have just been mentioned in connection with FIGS. 1 and 2. The element 110 should thus be understood to be representative for the anode stop 3, the first condenser lens 4 and its first pole shoe 40 and its second pole shoe 41, the condenser stop 6, the second condenser lens 8 and its first pole shoe 81 and its second pole shoe 81, the detection system 10 and its detectors 10a, 10b and the electrostatic objective lens 12 or the end cap, as it is known.

FIG. 3A) illustrates an electrically driveable mechanical adjustment mechanism in a two-part form. The first component comprises an electrically driveable mechanical adjustment mechanism 111, which is driven by the controller 20 via a line 113 and is able to position the element 110 in the x-direction. Accordingly, provision is made for a second component 112 of the electrically driveable mechanical adjustment mechanism that is able to be supplied with a signal and driven by the controller 20 via the line 114, such that the element 110 to be adjusted is able to be displaced or moved in the y-direction by way of the adjustment mechanism 112. It is possible for counter-bearings (not illustrated) to be formed on the element 110 at the diametrically opposing points to the starting points or application points of the adjustment mechanism 111, 112. This may be of particular significance in the case of magnetic lenses or magnetic lens components that are to be adjusted mechanically. It is also possible, in addition to the electrically driveable mechanical adjustment mechanism, to make provision for a mechanical fixing mechanism that is likewise electrically driveable and that is provided as a separate component or integrated with the electrically driveable mechanical adjustment mechanism.

The electrically driveable mechanical adjustment mechanism may be designed in various ways. An electrically driveable mechanical adjustment mechanism 111, 112 may for example comprise a stepper motor having a gear system. However, it is also possible for an actuator to be designed in the form of a piezo-element or as a combination of a stepper motor and a piezo-element. Possible embodiments of an electrically driveable mechanical adjustment mechanism and/or fixing mechanism may also be found in patent application DE 10 2022 114 098.9, which has not yet been laid open at the time of filing of the present patent application, the disclosure of which is incorporated in full into the present patent application by reference.

FIG. 3B) shows, by way of example, a Cartesian adjustment with a four-part electrically driveable mechanical adjustment mechanism 110. Here, in each case, two mutually opposing elements 111a, 111b and 112a, 112b are provided as adjustment mechanism. The controller 20 controls each of these adjustment mechanism 111a, 111b, 112a and 112b by way of appropriate signals, which are transmitted via the lines 113a, 113b, 114a and 114b. In the example shown, the control signals for pairwise-associated adjustment mechanism 111a, 111b and for 112a and 112b are synchronized and in opposition. This may be desirable for mechanical implementation, since positioning may thereby be carried out more accurately, because there is no need for any counter-bearings that could introduce inaccuracies into the adjustment.

In addition, it is possible to provide only a single electrically driveable mechanical adjustment mechanism, but only an adjustment in one direction is then normally possible. Therefore, an adjustment within the plane x, y that is oriented perpendicular to the particle-optical plane Z is of course possible. In addition, it is also possible for an electrically driveable mechanical adjustment in the z-direction, that is to say in the direction of the particle-optical axis Z, to be possible at least for some elements of the particle beam column 100. This concerns for example the particle source 1 relative to the extractor electrode 2 or else a sample stage 14, which may for example be height-adjustable in the Z direction.

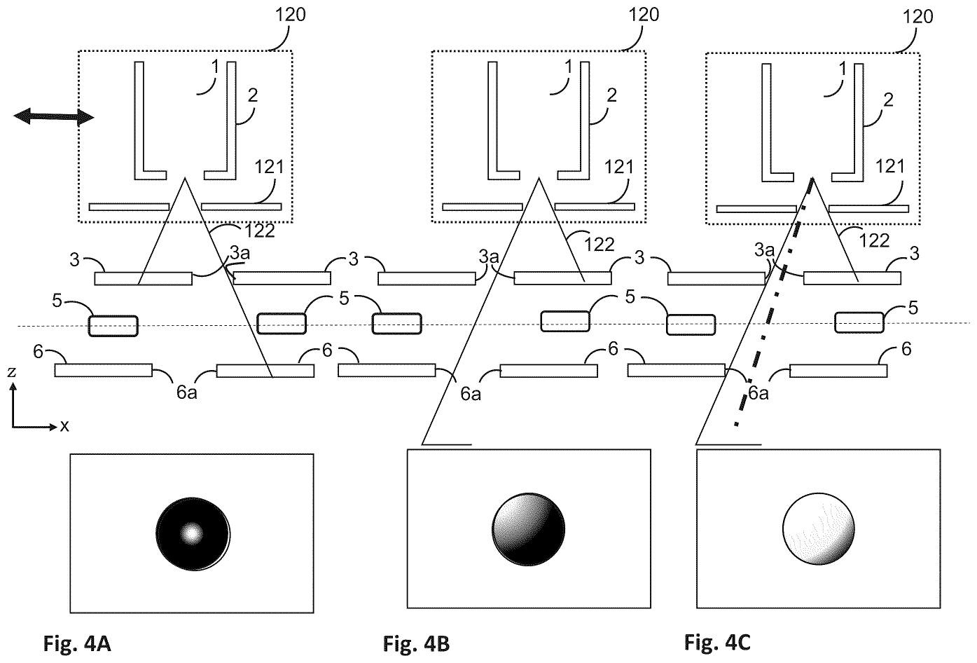

FIGS. 4A-4C schematically show a beam generator 120, which is able to be positioned by way of an electrically driveable mechanical beam head adjustment mechanism, as well as examples of raster images generated in different positions of the beam generator 120. In the example shown, the beam generator 120 comprises a particle source or tip 1, a suppressor electrode 2 arranged around it and an extractor stop 121. This assembly is able to be displaced or positioned as a whole as a beam generator 120, this being indicated in FIG. 4A by the large double-headed arrow at the top left. The capability of displacement may be achieved here within the plane x, y that is orthogonal to the particle-optical axis Z of the particle beam column 100. FIGS. 4A-4C however illustrates only a cross-sectional illustration in the xz-plane for reasons of simplification and clarity. In addition, the extractor stop 121 may be able to be displaced separately from the beam generator 120 in order to be able to align the particle emission straight onto the optical axis in the sample direction.

A conical particle beam 122 emerges from the beam generator 120. This particle beam 122 impinges on the anode stop 3. Depending on the relative position between the beam generator 120 and the anode stop 3, the particle beam 122 passes entirely or only partially, and centrally or only to the side, through the anode aperture 3a. In the case of a fixed relative position between the anode stop 3 and the condenser stop 6 with the associated openings 3a and 6a, respectively, the result of this, when the openings 3a, 6a are not aligned optimally with one another or not aligned exactly on the optical axis Z, is that in each case only a fraction of the originally generated particle beam 122 is also able to pass through the condenser aperture 6a and is available for scanning of the sample 13 or for corresponding image generation. In the example shown in FIG. 4A), only a very dark raster image with little intensity is able to be generated. A shadow image of the condenser aperture 6a is difficult to identify. In FIG. 4B), on the other hand, the intensity of the generated raster image is significantly higher, but the actually circular condenser aperture 6a in the image is now strongly cropped, that is to say cannot be identified as being ideally round. In FIG. 4C), on the other hand, the intensity is greatest, and the roundness of the imaged condenser aperture 6a is likewise largely guaranteed. However, it should be noted that the greatest roundness may be identified in FIG. 4A), whereas the greatest brightness may be identified in FIG. 4C). An optimal adjustment in the case of a fixed anode stop 3 and condenser stop 6 or in the case of a beam generator 120 able to move relative thereto is therefore present when the associated raster image has the greatest intensity. According to an embodiment of the disclosure, the associated raster image is generated in an operating mode in which the particle beam column 100 has the condenser lens system 4, 8 switched off and the objective lens system 11, 12 switched off. In this respect, the raster image is in general a shadow image of the condenser aperture 6a. By way of example, for the scanning process itself, it is possible to use the first deflection unit 5, which is arranged between the anode stop 3 and the condenser stop 6.

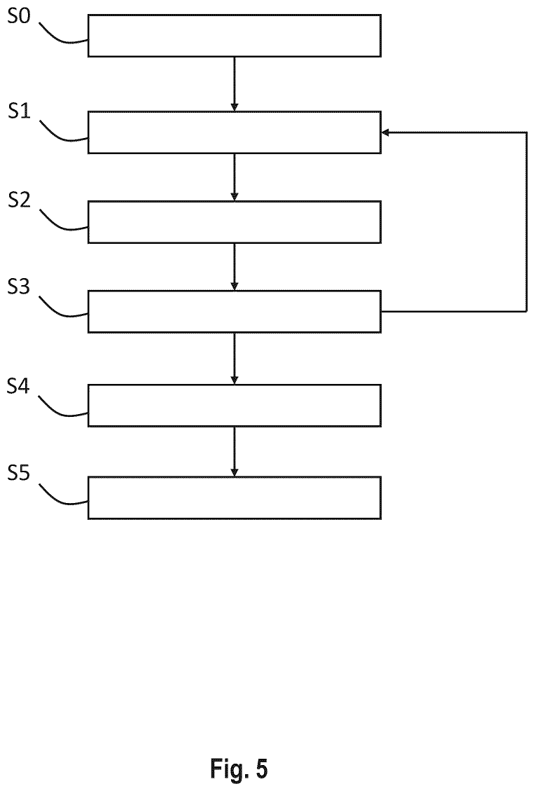

FIG. 5 schematically shows a method or a flowchart for the automated mechanical adjustment of a particle beam column 100 with reference to the example of a beam generator adjustment. In a first, initiating method step S0, a particle beam column, for example a particle beam column 100 as illustrated in FIGS. 1 and 2, is first provided.

In a further method step S1, the beam generator 120 is positioned in a position Pᵢⱼ by way of an electrically driveable mechanical beam head adjustment mechanism. In general, this electrically driveable mechanical beam head adjustment mechanism may be designed as described for example in general form in connection with FIGS. 3A-3B. The indices ij at the position Pᵢⱼ indicate that the beam generator can be positioned within a plane that is spanned for example by the axes x, y. In general, however, it is of course also possible to carry out positioning of the beam generator 120 by way of the electrically driveable mechanical beam head adjustment mechanism only in one direction.

In a further method step S2, the condenser stop 6 is scanned with the particle beam 122 by way of the first deflection unit 5, and a raster image Sᵢⱼ of the condenser stop 6 is generated by way of the detection system 10. Each position Pᵢⱼ of the beam generator 120 is thus assigned a raster image Sᵢⱼ. The detection system 10 itself may have a secondary electron detector, a backscattered electron detector, for example within the particle beam column, or else another type of detection system, for example a chamber detector. The generation of a raster image Sᵢⱼ is the decisive factor.

In a further method step S3, the raster image Sᵢⱼ is analysed with regard to the intensity of the condenser aperture 6a imaged thereon.

Steps S1 to S3 are then repeated, for example repeated multiple times.

Next, in a method step S4, a best raster image S_{best} is determined based on the analysis or on the analyses according to step S3.

In a further method step S5, the beam generator 120 is positioned, by way of the electrically driveable mechanical beam head adjustment mechanism, in a position P_{best} in which the best raster image S_{best} was generated. Thereafter, the beam generator 120 is thus arranged in the position P_{best} in which it is possible to record raster images S_{best} with the greatest intensity.

The method described in FIG. 5 may be further supplemented and/or extended. For example, it is possible to perform the method in two stages. In this case, in a first stage, the beam generator 120 may be displaced or repositioned, in each case in method step S1, over a first region with a first step width. Accordingly, in a second stage, positioning or movement is then carried out, in each case in method step S1, with a second step width that is smaller than the first step width. The region covered in the process in the second stage is smaller than the first region in the first stage. The second region can be a subregion of the first region. In other words, a rough adjustment may be performed first, followed by a finer adjustment of the beam generator 120.

According to an embodiment, the beam generator 120 is positioned in two mutually independent, for example orthogonal, directions x, y.

The beam generator 120 can be displaced between different positions with a constant step width, such as with a constant step width in each direction.

According to an embodiment of the disclosure, an order in which the positions Pᵢⱼ of the beam generator 120 are moved to is defined beforehand, and all of the positions Pᵢⱼ are also actually moved to. This may apply to all theoretically possible positions Pᵢⱼ, but it may also apply to all theoretically possible positions Pᵢⱼ of a certain stage or in the case of a certain fixedly set step width.

According to an exemplary embodiment of the disclosure, the raster images Pᵢⱼ are analysed after each displacement step and before the next displacement step, wherein a step width and/or a step direction for the respectively next displacement step or positioning step are/is ascertained adaptively based on the result of the analysis according to step S3. For example, it is possible, as soon as intensity is detected for the first time, to use a gradient-based method to find the global intensity maximum. The adaptive step width may then be selected depending on the intensity. Possible step widths are for example 500 μm in the case of intensity that is still low and for example 10 μm in the case of intensity that is already significantly higher.

Exemplary values for movement ranges of the beam generator 120 are 3 mm, 4 mm or 5 mm, and the accuracy achievable in the process should be sufficiently precise, for example better than or equal to 50 μm, better than or equal to 30 μm, better than or equal to 20 μm or better than or equal to 10 μm.

According to an embodiment of the disclosure, the best position P_{best} of the beam generator 120 is considered to have been reached and is defined as best position in the presence of at least one final termination criterion for a raster image S_{best}. By way of example, this may be a minimum intensity.

Moreover, it is possible for the adjustment method described above also to comprise the following method steps:
varying a z-position of the particle source 1 in the direction of the particle-optical axis Z by way of an electrically driveable mechanical source adjustment mechanism, and thus the distance of the particle source 1 from the extractor stop 2,
measuring an extractor current in the respective z-position,
determining the best z-position based on the measured extractor currents, and
positioning the particle source 1 in the best z-position by way of the electrically driveable mechanical source adjustment mechanism.

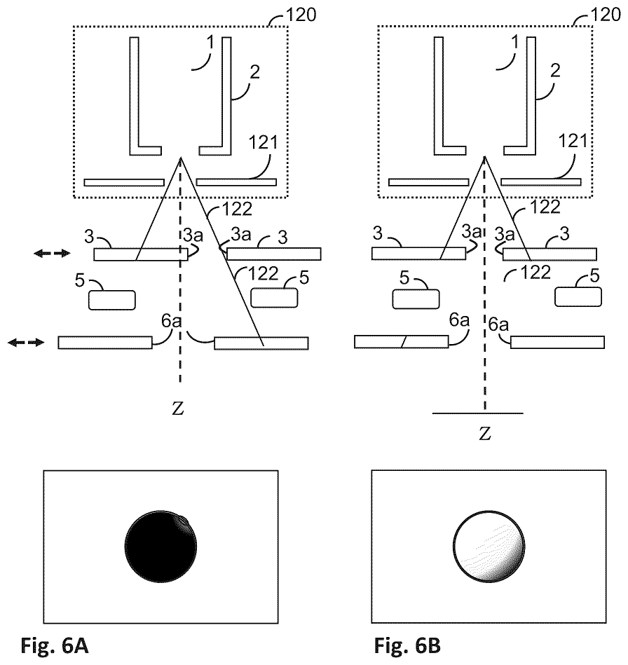

FIGS. 6A-6B schematically show a beam generator 120 having an extractor stop 121, an anode stop 3 and a condenser stop 6, wherein the anode stop 3 and the condenser stop 6 are each able to be positioned relative to the beam generator 120 by way of an electrically driveable mechanical anode stop adjustment mechanism or condenser stop adjustment mechanism, as well as examples of raster images generated in different positions of the stops 3, 6. The ability to move or adjust the anode stop 3 and the condenser stop 6 is again illustrated by the double-headed arrows. When the anode stop position APᵢⱼ and the condenser stop position BPₖₗ are able to be adjusted, the two stops 3, 6 are able to be adjusted independently of one another, but not completely separately from one another. Specifically, depending on the position of the condenser stop 6 or aperture stop 6, a different position of the anode stop is optimal. However, the general aim is to precisely align the anode aperture 3a, on the one hand, and the condenser aperture 6a, on the other hand, with the particle-optical axis Z. The shadow image or raster image of the condenser aperture 6a is then exactly round, on the one hand, and has a maximum intensity, on the other hand.

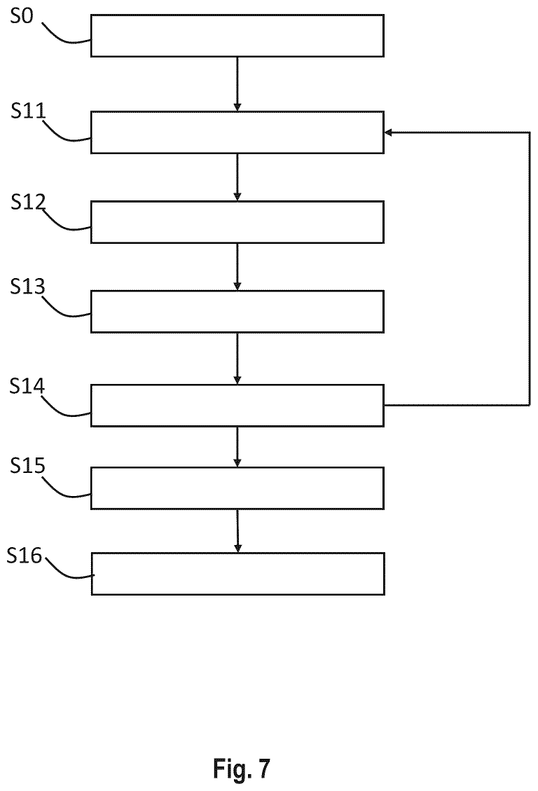

FIG. 7 schematically shows a flowchart or method for the automated mechanical adjustment of a particle beam column 100 with reference to the example of an anode stop and condenser stop adjustment. The method is performed in an operating mode in which the particle beam column 100 is operated with the condenser lens system 4, 8 switched off and with the objective lens system 11, 12 switched off. In a first method step S0, the particle beam column 100 is provided, as described above for example in connection with FIGS. 1 and 2.

In a method step S11, the anode stop 6 is positioned in an anode stop position APᵢⱼ by way of an electrically driveable mechanical anode stop adjustment mechanism.

In a method step S12, the condenser stop 6 is positioned in a condenser stop position BPₖₗ by way of an electrically driveable mechanical condenser stop adjustment mechanism.

In a method step S13, the condenser stop 6 is scanned with the particle beam 122 by way of the first deflection mechanism 5 and a raster image Sᵢⱼₖₗ of the condenser aperture 6a is generated by way of the detection system 10. The indexing of the raster image Sᵢⱼₖₗ in this case indicates that the raster image is assigned both an anode stop position APᵢⱼ and a condenser stop position PBₖₗ.

In a method step S14, the raster image Sᵢⱼₖₗ is analysed with regard to intensity and shape of the condenser aperture 6a imaged thereon.

Method steps S11 to S14 are then repeated, for example multiple times.

In a method step S15, a best raster image S_{best} is determined based on the analyses according to step S14.

In step S16, the anode stop 3 is then positioned in a position AP_{best} by way of the electrically driveable mechanical anode stop adjustment mechanism and the condenser stop 6 is positioned in a position BP_{best} by way of the electrically driveable mechanical condenser stop adjustment mechanism, wherein the positions AP_{best} and BP_{best} correspond to the positions of the anode stop 3, respectively of the condenser stop 6, in which the best raster image S_{best} was recorded.

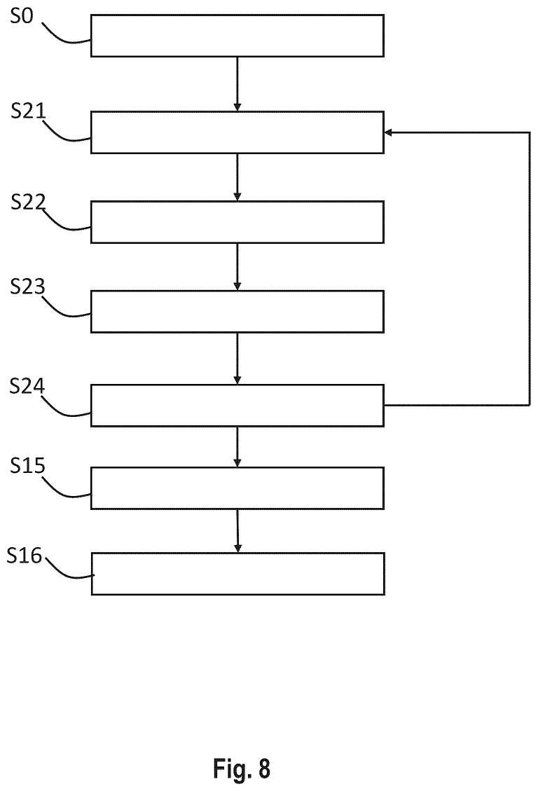

FIG. 8 schematically shows a further method for the automated mechanical adjustment of a particle beam column 100 with reference to the example of an anode stop and condenser stop adjustment. The method in this case comprises the following steps: First of all, in a method step S0, the particle beam column 100 is provided, as already described several times above.

In a method step S21, positions APᵢⱼ of the anode stop 3 are first varied while keeping a fixed condenser stop position until the intensity of a generated raster image Sᵢⱼₖₗ exceeds a set threshold value.

In a method step S22, positions BPₖₗ of the condenser stop 6 are then varied while keeping a fixed position of the anode stop 3 until the shape of the imaged condenser aperture 6a has the greatest accuracy, for example the best roundness in the case of a circular condenser aperture, wherein the fixed position of the anode stop 3 is that position of the anode stop 3 in which the threshold value was exceeded in step S21.

In method step S23, positions of the anode stop 3 are then varied again with a new fixed position of the condenser stop 6 until the intensity of a generated raster image Sᵢⱼₖₗ reaches a maximum, wherein the new fixed position of the condenser stop 6 is that position in which the greatest shape accuracy, for example the best roundness in the case of a circular aperture, was ascertained in step S22.

In step S24, positions of the condenser stop 6 are varied again with a new fixed position of the anode stop 3 until the shape of the imaged condenser aperture 6a has the greatest accuracy, for example the best roundness in the case of a circular aperture, wherein the new fixed position of the anode stop 3 is that position of the anode stop 3 in which the maximum intensity was reached in step S23.

Steps S21 to S24 may be repeated, for example repeated multiple times. For example, method steps S21 to S24 may be repeated until a termination criterion for the intensity and/or the shape accuracy, for example the roundness of the imaged condenser aperture 6a, is satisfied for a best raster image S_{best}. The best raster image S_{best} is thus then determined according to method step S15.

Next, in a method step S16, the anode stop 3 is positioned in a position AP_{best} by way of the electrically driveable mechanical anode stop adjustment mechanism and the condenser stop 6 is positioned in a position BP_{best} by way of an electrically driveable mechanical condenser stop adjustment mechanism, wherein the positions AP_{best} and BP_{best} correspond to the positions of the anode stop 3, respectively of the condenser stop 6, in which the best raster image S_{best} was recorded.

Both in the method according to FIG. 7 and in the method according to FIG. 8, it is possible for the anode stop 3 to be positioned in two mutually independent, for example orthogonal, directions x, y and/or for the condenser stop 6 to be positioned in two mutually independent, for example orthogonal directions x, y.

In addition, it is again possible for the anode stop 3 to be displaced between different positions with a constant step width, for example constant step width in each direction; in addition or as an alternative, the condenser stop 6 may be displaced between different positions with a constant step width, for example constant step width in each direction.

According to an embodiment of the disclosure, the anode stop may be displaced between different positions with an adaptive step width, wherein an adaptation of the step width is based on the ascertained intensity in at least one raster image Sᵢⱼₖₗ. In addition or as an alternative, the condenser stop 6 may be displaced between different positions with an adaptive step width, wherein an adaptation of the step width is based on the ascertained shape accuracy, for example the roundness, of the imaged condenser stop 6 in at least one raster image Sᵢⱼₖₗ. Gradient-based automated image recognition methods may also again be used here.

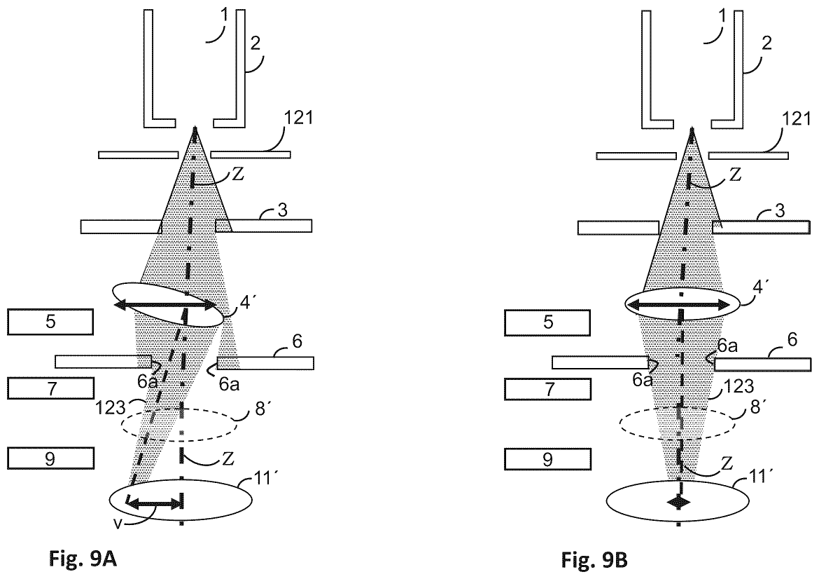

The disclosure also makes it possible to automatically mechanically adjust a condenser lens system. The condenser lens system may in this case be either a double condenser or a single condenser. In general, the condenser lens system may also have further condenser lenses. In general, it is possible, by way of a mechanical adjustment method according to the disclosure, to correct both a tilt and a displacement of the condenser lenses with respect to the particle-optical axis Z. FIGS. 9A-9B schematically show a particle-optical beam path in a condenser lens system or the light-optical analogue thereof. A first for example magnetic condenser lens 4′ (the dash in this case illustrates the light-optical analogue) is arranged between the anode stop 3 and the condenser stop 6. A second condenser lens 8′, which is arranged in the particle-optical beam path downstream of the condenser stop 6, is switched off in the example shown in FIG. 9A). This switching off is illustrated by the dashing of the light-optical analogue. In the example shown in FIG. 9A), the condenser lens 4′ is displaced, on the one hand, relative to the particle-optical axis Z, and tilted, on the other hand. As a result, a beam focused by the condenser lens 4′ does not enter an objective lens system 11′ (that is to say the optical analogue to the particle-optical objective lens 11) in the direction of the particle-optical axis Z. Therefore, a displacement V also occurs on a sample 13 to be scanned. If the refractive power of the first condenser lens 4′ changes, then the displacement also changes. A change in the refractive power of the condenser lens 4′ may in turn be achieved in several ways; by modulating the lens current in the condenser lens 4 (this only works in particle optics), on the one hand, or alternatively by changing the acceleration voltage of the particle source 1. Wobbling, that is to say periodically changing the refractive power of the condenser lens 4, makes it possible to visualize the change in the displacement V in a sequence of raster images. If, by contrast, as shown in FIG. 9B, the condenser lens 4 or 4′ is not tilted, but rather is displaced at most slightly, then there is no further displacement V during a change in refractive power. Instead, an underfocus or overfocus is periodically generated centrally around the optical axis Z.

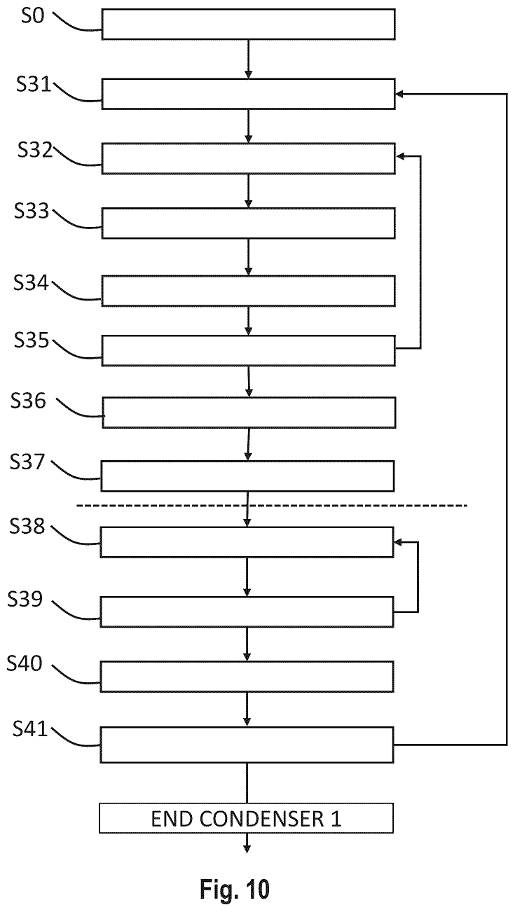

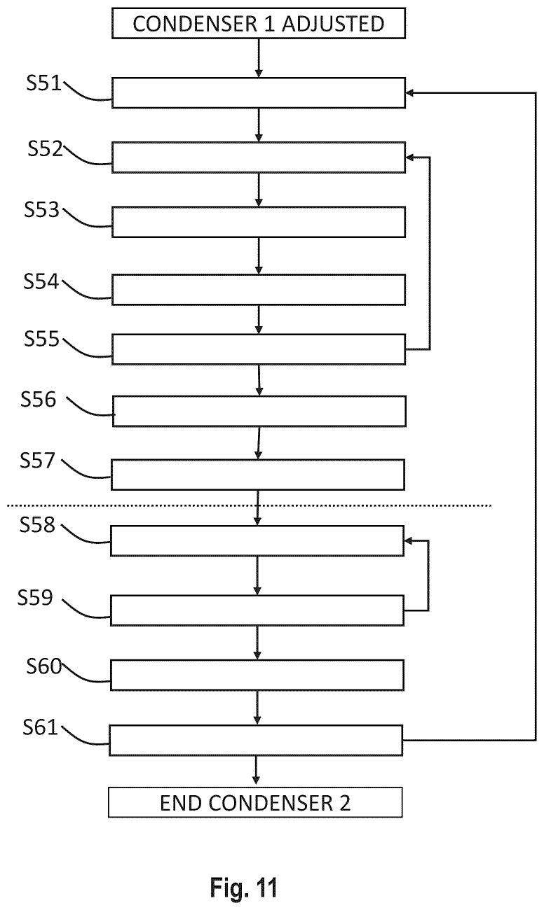

A specific method for an automated mechanical adjustment of a condenser lens system is now described by way of example in FIGS. 10 and 11. FIG. 10 in this case illustrates an automated mechanical adjustment of a first condenser lens and FIG. 11 illustrates an automated mechanical adjustment of the second condenser lens 8. It will be assumed here that each of the condenser lenses 4, 8 has both an upper pole shoe 40, 80 and a lower pole shoe 41, 81. Each of these pole shoes 40, 41, 80, 81 is in this case able to be displaced for example in two mutually orthogonal directions by way of a corresponding electrically driveable mechanical adjustment mechanism. The corresponding signals for this displacement are again provided by the controller 20. If an upper pole shoe and a lower pole shoe are each displaced in the same direction and by the same magnitude, then this corresponds to a displacement of the entire condenser lens or the condenser lens as a whole. This makes is possible to correct a displacement of the condenser lens 4, 8 as a whole. A relative displacement of the upper pole shoe 40 relative to the lower pole shoe 41 of the first condenser lens 4 results in a tilt of the generated magnetic field within the condenser lens 4. To correct a tilt, therefore, a mechanical tilt of the condenser lens 4 is not corrected, but rather a relative displacement of the upper pole shoe 40 in relation to the lower pole shoe 41, for example only a movement of the upper pole shoe 40 while keeping a fixed position of the lower pole shoe 41, is performed. The same is possible for a correction of any tilt of the second condenser lens 8.

That being the, the flowchart in FIG. 10 is now described in more detail for the adjustment, initially, of the first condenser 4: In a first method step S0, a particle beam column 100 is again first provided. In this process, this can be already pre-adjusted such that a particle beam 122 is aligned with the condenser aperture 6a in a manner oriented optimally with the particle-optical axis Z when the condenser lens 4 is switched off.

The method in this case can be performed in an operating mode in which the particle beam column 100 is operated with the objective lens system switched off. An objective lens system excited only to an insignificant extent is also understood to be switched off.

In a method step S31, the first condenser lens 4 with a first pole shoe 40 and a second pole shoe 41 is positioned in a condenser lens position K1Pijkl. This indexing indicates that the overall position of the first condenser lens 4 is defined by a total of four parameters.

In a method step S32, the first condenser lens 4 is excited with a first weak excitation strength and, in the process, the condenser lens excitation is wobbled or an acceleration voltage of the beam generator 1 is wobbled.

In a further method step S33, multiple raster images are generated by way of the detection system 10 during the wobbling, wherein, for each raster image, the particle beam 122, 123 is raster-scanned over the object 13 by way of the scanning device 50.

In a method step S34, during the wobbling, a displacement V of the emission spot imaged in the raster images is determined. This displacement varies depending on the current variation of the condenser lens excitation or the acceleration voltage respectively present.

In a method step S35, the position of only the first pole shoe 40 of the condenser lens 4 is then varied by way of an electrically driveable mechanical first pole shoe adjustment mechanism. Method steps S32 to S35 are then repeated, possibly multiple times.

In a method step S36, a position of the first pole shoe 40 in which the displacement of the emission spot in the raster images is reduced, for example at a minimum, is ascertained.

In a method step S37, only the first pole shoe 40 is then positioned in the position ascertained in step S36 by way of the electrically driveable mechanical first pole shoe adjustment mechanism.

Method steps S32 to S37 have substantially corrected a tilt of the condenser lens 1 for the first time. This correction section is indicated by the dashing between method steps S37 and S38 in FIG. 10. The method then continues with a first correction of a displacement of the condenser lens 4 in relation to the optimal alignment on the particle-optical axis Z:

In a method step S38, the excitation of the first condenser lens 4 is increased. In each case, multiple raster images are detected here by way of the detection system, wherein, for each raster image, the particle beam 123 is raster-scanned over the object 13 by way of the scanning device 50. An intensity is determined for each raster image, wherein the excitation of the condenser lens 4 is increased until the intensity in one of the raster images falls below a threshold value. Specifically, a focal point is then near the condenser stop plane and a majority of the beam 122 is cut off by the condenser stop.

In a further method step S39, the first condenser lens 4 is displaced as a whole, wherein the first pole shoe 40 is displaced by way of the electrically driveable mechanical first pole shoe adjustment mechanism and wherein the second pole shoe 41 is displaced by way of the electrically driveable mechanical second pole shoe adjustment mechanism. The magnitude and direction of the displacement are identical for both pole shoes, but this is not necessarily the case for the step width for the respective displacement.

Method steps S38 to S39 can be repeated, for example repeated multiple times.

Then, in a method step S40, a position of the first condenser lens 4 in which the intensity determined in step S38 is at a maximum or in which the threshold value is no longer fallen below is ascertained.

In a further method step S41, the first condenser lens 4 is positioned as a whole in the condenser lens position K1Pijkl ascertained in step S40, wherein the first pole shoe 40 is displaced by way of the electrically driveable mechanical first pole shoe adjustment mechanism and wherein the second pole shoe 41 is displaced by way of the electrically driveable mechanical second pole shoe adjustment mechanism.

The sequence of method steps S31 to S41 is repeated, for example repeated multiple times. By way of example, the repetition of the sequence ends when a displacement ascertained in step S36 is minimized globally and/or when an intensity ascertained in step S40 is maximized globally.

Of course, in the adjustment method described in FIG. 10, the second condenser lens 80 is switched off or substantially switched off.

The second condenser lens 8 may then in turn for its part be mechanically adjusted after the mechanical adjustment of the first condenser lens 4 is complete. One example of an algorithm for this is illustrated in FIG. 11. The first condenser lens 4 is in this case already adjusted and for example switched off for the following method steps.

In a method step S51, the second condenser lens 8 with a first pole shoe 81 and a second pole shoe 82 is positioned in a condenser lens position K2Pijkl.

In a method step S52, the second condenser lens 8 is excited with a first weak excitation strength and, in the process, the condenser lens excitation is wobbled or the acceleration voltage of the beam generator 120 is wobbled.

In a method step S53, multiple raster images are recorded by way of the detection system 10 during the wobbling, wherein, for each raster image, the particle beam 123 is raster-scanned over the object 13 by way of the scanning device 50.

In a method step S54, a displacement V of the emission spot imaged in the raster images during the wobbling is determined.

In method step S55, a position of only the first pole shoe 81 of the second condenser lens 8 is varied by way of an electrically driveable mechanical first pole shoe adjustment mechanism of the second condenser lens 8. Method steps S52 to S55 are repeated, for example repeated multiple times.

In method step S56, a position of the first pole shoe 81 of the second condenser lens 8 in which the displacement of the emission spot V in the raster images is reduced, for example at a minimum, is then ascertained.

In method step S57, only the first pole shoe 81 of the second condenser lens 8 is positioned in the position ascertained in step S56 by way of the electrically driveable mechanical first pole shoe adjustment mechanism of the second condenser lens 8.

Method steps S52 to S57 here substantially allow correction of any tilt of the second condenser lens 8 with respect to the particle-optical axis Z. After this tilt correction, a displacement correction may be carried out (steps S58 et seqq.).

In method step S58, the second condenser lens 8 is excited with a second excitation strength, which is greater than the first excitation strength, and an associated raster image is recorded by way of the detection system 10 and a position deviation V of the focus spot with respect to the optical axis Z is ascertained.

In step S59, the second condenser lens 8 is displaced as a whole, wherein the first pole shoe 81 is displaced by way of the electrically driveable mechanical first pole shoe adjustment mechanism of the second condenser lens 8 and wherein the pole shoe 82 is displaced by way of the electrically driveable mechanical second pole shoe adjustment mechanism of the second condenser lens 8.

Method steps S58 and S59 are then repeated, possibly multiple times.

In method step S60, a position of the second condenser lens 8 in which the position deviation V ascertained in step S58 is at a minimum is ascertained.

In step S61, the second condenser lens 8 is positioned as a whole in the condenser lens position K2Pijkl ascertained in step S60, wherein the first pole shoe 81 is displaced by way of the electrically driveable mechanical first pole shoe adjustment mechanism of the second condenser lens 8 and wherein the second pole shoe 82 is displaced by way of the electrically driveable mechanical second pole shoe adjustment mechanism of the second condenser lens 8.

The sequence of method steps S51 to S61 may again be repeated, for example repeated multiple times. A tilt correction and a displacement correction are thereby carried out iteratively and alternately until both the tilt and the displacement have been corrected well or as optimally as possible.

In the case of the automated mechanical adjustment of the condenser lens system as well, it is of course possible to design corresponding step widths for the adjustment so as to be constant or adaptive.

The automated mechanical adjustment method described in connection with FIGS. 10 and 11 concerns a double condenser with very extensive setting possibilities. For example, the upper and lower pole shoe 40, 41 of the first condenser lens 4 and the upper and lower pole shoe 80, 81 of the second condenser lens 8 were each separately adjustable. This is also highly desirable for example for double condenser systems.

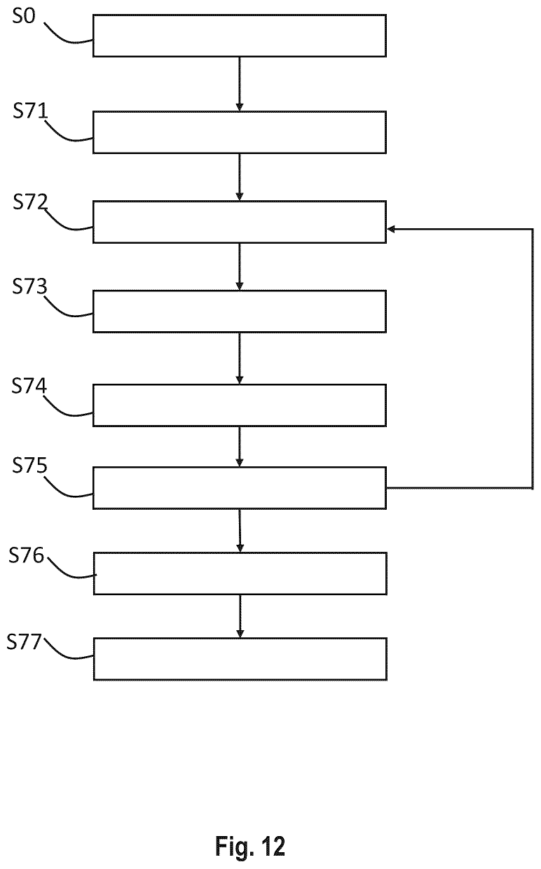

However, there are single condenser systems of simpler design. In these systems, it may of course again be possible to adjust an upper pole shoe 40 separately from a lower pole shoe 41. However, it has turned out that, in single condenser systems, a displacement of the single condenser as a whole is often sufficient for a mechanical adjustment. As a result, the adjustment may be carried out more quickly as a whole and fewer restrictions are placed on the design of the particle beam column 100. This is because any tilt of a single condenser leads only to a negligible error in the mechanical adjustment. Specifically, a corresponding mechanical adjustment method may be designed as follows, as illustrated in FIG. 12 in the form of a flowchart:

In an initial method step S0, a particle beam column 100 having a single condenser is provided, as shown for example in FIG. 2.

In a method step S71, the condenser lens 4 is positioned in a condenser lens position KPij. Only two indices i, j are indicated here, since the condenser lens is only displaced as a whole. Its position may therefore be defined in full by two indices.

In a method step S72, the condenser lens 4 is excited with a first weak excitation strength and, in the process, the condenser lens excitation is wobbled or an acceleration voltage of the beam generator 120 is wobbled.

In a method step S73, multiple raster images are generated by way of the detection system 10 during the wobbling, wherein, for each raster image, the particle beam 122, 123 is raster-scanned over the object 13 by way of the scanning device 50.

In a method step S74, a displacement V of the emission spot imaged in the raster images during the wobbling is determined.

In a method step S75, the position of the condenser lens 4 or of the single condenser 4 is varied by way of an electrically driveable mechanical condenser lens adjustment mechanism.

Method steps S72 to S74 may be repeated, and may for example be repeated multiple times.

In a method step S76, a position of the condenser lens 4 in which the displacement V of the emission spot in the raster images is reduced, for example at a minimum, is ascertained.

In a method step S77, the condenser lens 4 is positioned in the position ascertained in step S76 by way of the electrically driveable mechanical condenser lens adjustment mechanism.

The detection system of the particle beam column 100 and a method for the automated mechanical adjustment of the detection system will be discussed in more detail below. If detectors 10 are used in a particle beam column 100 and are arranged within the particle beam column and for example so as to run around the optical axis of the particle beam column, then these detectors 10 may be automatically mechanically adjusted. It is often the case that what are known as ring detectors are used within the particle beam column 100. A system consisting of two ring detectors is often used, wherein the two ring detectors are arranged along the particle-optical axis Z so as to run around it and are arranged spaced apart from one another. By way of example, the first detector is a backscattered electron detector and the second detector is a secondary electron detector. Reference is also made to the explanations in connection with the description of FIGS. 1 and 2.

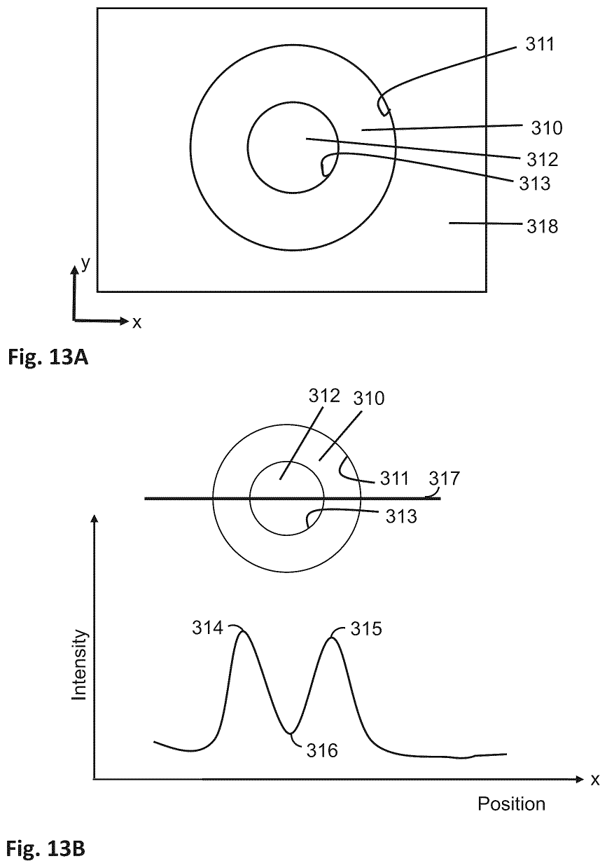

If a raster image is then recorded using the first, or upper detector (backscattered electron detector), then this upper first detector is basically shaded by the second detector (secondary electron detector) located underneath it. Furthermore, both detectors each have a detector hole in the form of a circular detector opening. If a raster image is then generated by way of the first detector with only very low magnification, then the detector holes may each be depicted in this raster image, specifically in the same raster image: This is illustrated by way of example in FIG. 13A). Specifically, a raster image with relatively low magnification is shown schematically. It is possible to see a central circle 312 and a brighter circular ring 310 in front of a substantially dark background 318. The edge 313 of the circle 312 in this case represents the detector hole of the first detector 10a or of the backscattered electron detector. The bright circular ring 310 is bounded externally by the detector hole 311 of the backscattered electron detector or second detector 10b. The raster image shown schematically by way of example was recorded in this case with very low magnification, for example with 100× magnification, and a high contrast was also set for the raster image. Of course, detector holes are not recorded in “normal” raster images by way of the electron beam microscope or SEM 100, and the detector holes 311, 313 are no longer able to be seen or do not cause any problems in the images with higher magnification. Nevertheless, images of the detector holes 311, 313 may then be used for adjustment purposes. Ideally, the circle 312 and the circular ring 310 are specifically arranged concentrically to one another and also arranged perfectly around the particle-optical axis Z of the particle beam column 100. The latter condition is met if both the circle 312 and the circle 310 or circular ring 310 are located exactly in the centre of the raster image.

Image analysis methods that are known per se may then be used to ascertain in each case the current position of the two ring detectors 10a, 10b, and these may also be displaced or positioned by way of appropriately provided electrically driveable mechanical detector adjustment mechanism. One example of an image analysis is shown in FIG. 13B), in which a sectional profile of the raster image has been generated along the line 317. In the graph, intensity is plotted against position in the x-direction. It is possible to see two maxima 314, 315 that are clearly separate from one another. The minimum 316, which corresponds to the circle centre or circular ring centre, is located between them. It is thus possible to detect and of course also correct deviations from the ideal position.

As an alternative, it is of course also possible to provide only one detector and to adjust this in an electrically driven manner, for example using a central alignment of an imaged detector hole 311, 313 within a raster image.

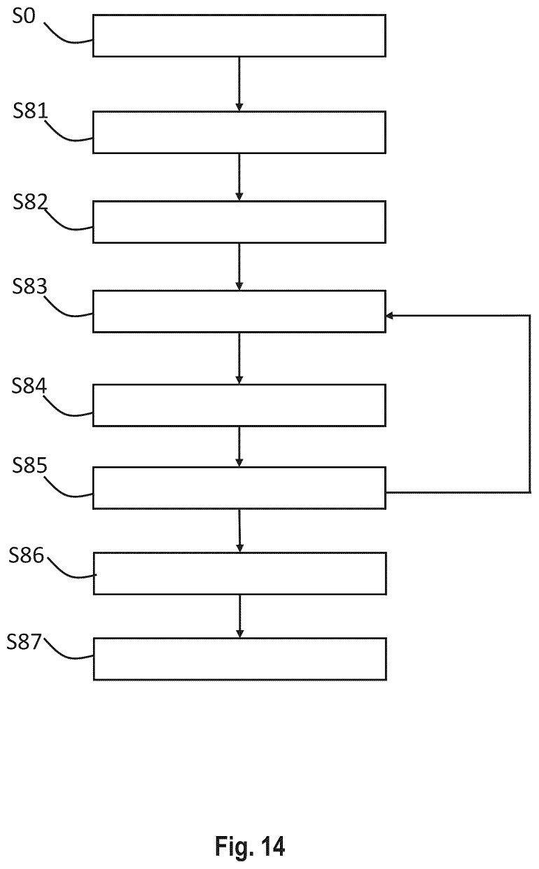

FIG. 14 shows one example of an algorithm able to be used for this purpose. First of all, in a first method step S0, provision is made for a particle beam column 100 having a detection system 10 for detecting interaction particles, which detection system is arranged within the particle beam column 100 between the condenser lens system 4, 8 and the objective lens system 11, 12 and so as to run, for example run annularly, around the optical axis Z of the particle beam column 100. In this case, the detection system 10 has a first detector 10a having a first detector hole 313 and a second detector 10b having a second detector hole 311 for the passage of the particle beam 122, 123, wherein the first detector 10a is arranged above the second detector 10b with respect to the particle-optical beam path. The method for adjusting the detection system may, for example in an operating mode in which the particle beam column is operated with the objective lens system switched off, have the following steps:

In a method step S81, the first detector 10a is positioned in a first position D1ij by way of a first electrically driveable mechanical detector adjustment mechanism.

In a method step S82, the second detector 10b is positioned in a second position D2ij by way of a second electrically driveable mechanical detector adjustment mechanism.

In method step S83, the object 13 is scanned by way of the scanning device 50 and a raster image is generated by way of the first detector 10a with a magnification that is chosen to be so small that the raster image images both the detector hole 313 of the first detector 10a as a first circle 312 and the detector hole 311 of the second detector 10b as a second circle or circular ring 310.

In a method step S84, the position of the first circle 312 is determined and the position of the second circle or circular ring 310 is determined in the raster image. For this purpose, for example, the circle centre is determined in each case.

In method step S85, the position D1ij of the first detector 10a and/or the position D2ij of the second detector 10b is varied. Method steps S83 to S85 are repeated, for example repeated multiple times.

In method step S86, a position D1_{best} of the first detector 10a and a position D2_{best} of the second detector 10b in which the first circle 312 and the second circle or circular ring 310 are aligned concentrically with one another and/or in which both circles or the circle 312 and the circular ring 310 are arranged exactly in the image centre of the raster image are ascertained.

In method step S87, the first detector 10a is then positioned in the position D1_{best} by way of the first electrically driveable mechanical detector adjustment mechanism and the second detector 10b is positioned in the position D2_{best} by way of the second electrically driveable mechanical detector adjustment mechanism.

The method may in this case comprise the method step of generating sectional profiles of the raster images and automatically detecting the circle centres in the raster images by applying gradient methods in the sectional profiles. An image contrast can be increased before sectional profiles are generated. The automated image evaluation may thereby be improved by way of routines that are already known per se.

According to an example, the first detector 10a is a backscattered electron detector and/or the second detector 10b is a secondary electron detector.

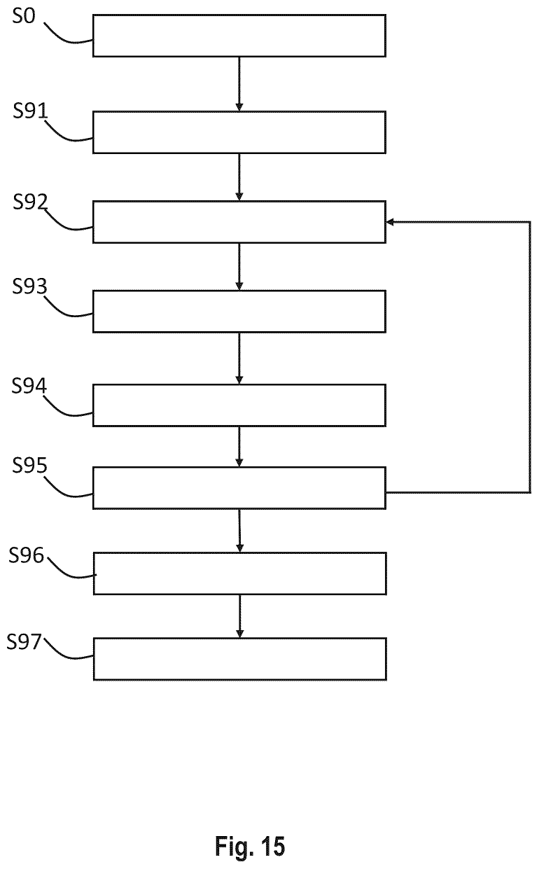

The objective lens system having a magnetic objective lens 11 and an electrostatic objective lens 12, the end cap, as it is known, has already been described briefly in the description of FIGS. 1 and 2. Whereas the magnetic objective lens 11 is normally not mechanically automatically adjustable, this limitation does not apply to the electrostatic objective lens portion 12 according to the present disclosure: The end cap 12 is substantially an electrode that is able to be positioned very well by way of an electrically driveable mechanical objective lens adjustment mechanism. One example of a routine is described in FIG. 15.

First of all, a particle beam column 100 is provided in method step S0. The following method steps are then carried out in an operating mode in which the condenser lens system 4, 8 is switched on, and in which the magnetic objective lens 11 is switched on and the particle beam 122 is thus focused onto the object 122:

In a method step S91, the electrostatic objective lens is positioned in a first position OLij.

In a method step S92, the electrostatic objective lens 12 is excited with a first excitation strength and, in the process, the excitation of the electrostatic objective lens 12 is wobbled or an acceleration voltage of the beam generator 120 is wobbled (please check!).

In a method step S93, multiple raster images are recorded by way of the detection system 10 during the wobbling, wherein, for each raster image, the particle beam 122 is raster-scanned over the object 13 by way of the scanning device 50.

In a method step S94, a displacement of the focus spot imaged in the raster images during the wobbling is determined. The underlying mechanism is the same as has already been described in connection with the condenser lens system 4, 8.

In method step S95, the position of the electrostatic objective lens 12 is varied by way of an electrically driveable mechanical objective lens adjustment mechanism.

Method steps S92 to S95 are repeated, for example repeated multiple times.

In step S96, a position of the electrostatic objective lens 12 in which the displacement of the focus spot in the raster images is reduced, for example at a minimum, is ascertained.

In step S97, the electrostatic objective lens 12 is positioned in the position ascertained in step S96 by way of the electrically driveable mechanical objective lens adjustment mechanism. In this case the electrostatic objective lens 12 again can be positioned in a plane orthogonal to the particle-optical axis Z by way of the electrically driveable mechanical objective lens adjustment mechanism.

In the algorithm described with reference to FIG. 15, it has ideally been assumed that the particle beam already enters the magnetic objective lens 11 optimally, that is to say centrally. This alignment may be achieved for example through the following method steps, which may be performed before method steps S91 to S97 described in FIG. 15:
switching off the electrostatic objective lens 12;
wobbling an excitation of a condenser lens 4, 8 in order to change an aperture angle of the particle beam 122; and/or
adjusting the particle-optical beam path by way of electrostatic deflectors 5, 7, 9 such that the particle beam 122 passes through the magnetic objective lens 11 in a centred manner.

The described automated adjustment methods may be combined in full or in part with one another. According to an embodiment of the disclosure, a method for the mechanical adjustment of a particle beam column 100 basically comprises the following steps:
mechanically adjusting the beam generator 120, anode stop 3 and/or condenser stop 6 relative to one another as described above in multiple variant embodiments; and/or
mechanically adjusting the condenser lens system 4, 8 as described above in multiple variant embodiments; and/or
mechanically adjusting the detection system 10 as described above in multiple variant embodiments; and/or
mechanically adjusting the objective lens system as described above in multiple variant embodiments.

The particle beam column can be mechanically adjusted from top to bottom, that is to say starting from the particle beam generator. This successively automated mechanical adjustment makes it possible to achieve particularly precise mechanical adjustment. Propagation of errors is avoided as far as possible.

Of course, the mechanical adjustment strategies may also be combined with electrical adjustment strategies. By way of example, the entire adjustment method furthermore comprises at least one of the steps listed below:
electrically adjusting the particle beam column 100 by setting electrostatic and/or magnetic deflection elements 5, 7, 9;
setting an objective lens current;
setting the detection system 10 with regard to brightness and/or contrast.

The above-described routines for automated mechanical adjustment may be combined in full or in part with one another, provided that no technical contradictions arise as a result.

It is also pointed out once again that the adjustment routines may be programmed as program code. This program code may be able to be loaded into a controller 20 of the particle beam column 100. When executing the program code or the corresponding program codes, a particle beam column 100 may therefore be controlled such that the method according to the disclosure is carried out as described above in multiple variant embodiments.

A particle beam column 100 that is configured to carry out the method as described above in multiple variant embodiments and having a controller 20 into which a computer program product as described above is loaded is likewise part of the disclosure.

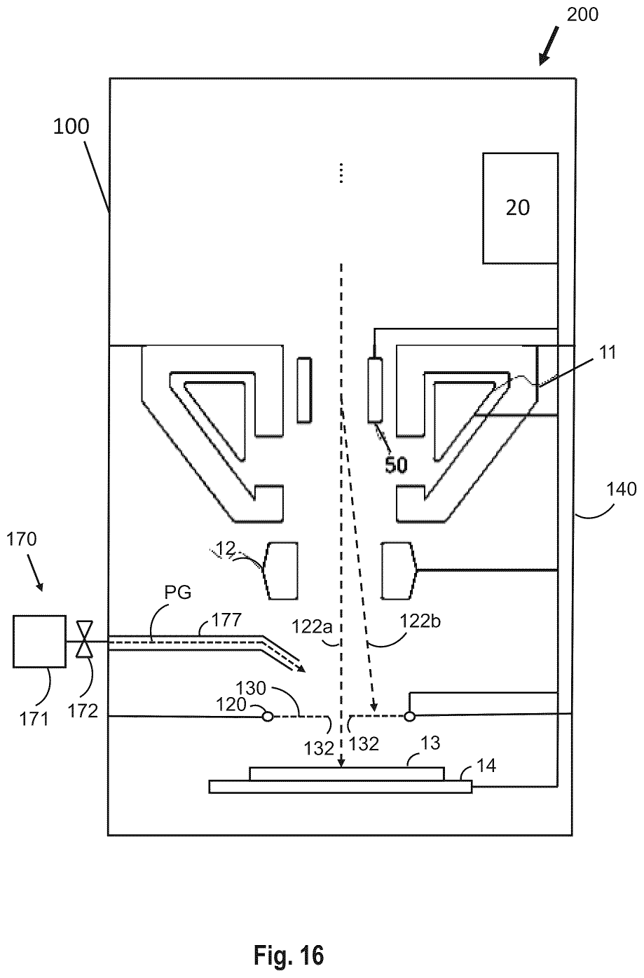

FIG. 16 schematically shows a device 200 having a particle beam column 100 according to the disclosure for analysing and/or processing a sample 13. The sample 13 may for example be a lithography mask having a feature size in the range of 10 nm to 100 μm. For example, it may be a transmissive lithography mask for DUV lithography (DUV: “Deep Ultra Violet”, operating light wavelengths in the range of 30 to 250 nm) or a reflective lithography mask for EUV lithography (EUV: “Extreme Ultra Violet”, operating light wavelengths in the range of 1 to 30 nm). Processing operations that are performed on the sample 13 with the device 200 may comprise for example etching processes, in which a material is locally removed from the surface of the sample 13, deposition processes, in which a material is locally applied to the surface of the sample 13, and/or similar locally activated processes, such as forming a passivation layer or compacting a layer.

The particle beam column or electron beam column 100 has a vacuum housing 140 that is evacuated for example to a residual gas pressure of 10⁻⁶ mbar to 10⁻⁸ mbar. An opening for the electron beam 122a is arranged on the underside. The opening itself is covered by a shielding element 130 that is secured on the opening by way of a holding element 133. By way of example, the holding element 133 comprises multiple screws in order to screw the shielding element 130 to the particle beam column 100.

The shielding element 130 is in two-dimensional form and comprises an electrically conductive material. A potential may be applied to the shielding element 130 by way of the controller 20. By way of example, the shielding element 130 may be at ground potential. The shielding element 130 is thus configured to shield an electric field. Such a field to be shielded may be generated for example by charging the sample 13 by way of the particle beam 122a. It may therefore be highly expedient to shield the interior of the particle beam column 100, for example in the case of samples 13 that are electrically non-conductive or only slightly electrically conductive.

FIG. 16 illustrates a process gas supply unit 170 by way of example. The particle beam column 100 is illustrated only in parts. However, it may for example be designed as in FIG. 1 or 2. The process gas supply unit 170 comprises a process gas reservoir 171, which is able to introduce process gas PG into the particle beam column 100 by way of a process gas line 173. The introduction of the process gas PG may in this case be regulated by way of a valve 172; the controller 20 of the particle beam column 100 or else a separate controller (not illustrated) may in turn be used for control and regulation purposes.

In addition to the pure shielding function of the shielding element 130, it is known practice to use the shielding element 130 for system qualification purposes as well. For this purpose, the shielding element 130 may have one or more test structures. The controller 20 of the particle beam column 100 makes it possible to direct a particle beam 122b onto the shielding element 130 instead of through the opening 132 in the shielding element 130.

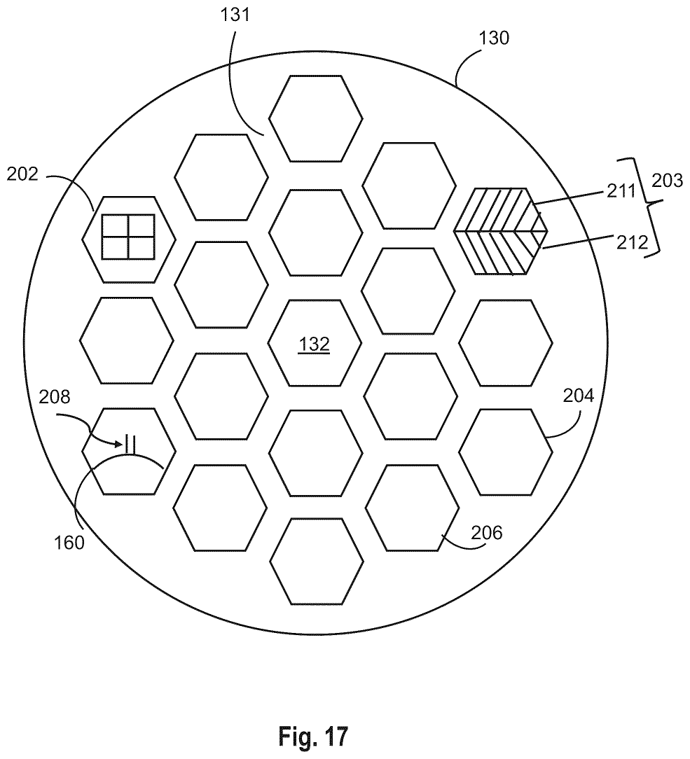

FIG. 17 schematically shows such a shielding element 130. The shielding element 130 comprises a mesh structure 131 and various through-openings, of which the central through-opening is designated with reference sign 132. The hexagonal through-openings in the example shown serve here as a possible passage for the process gas PG and as a possible passage for the particle beam. The shielding element 130 itself continues to serve as a shield. In addition, a test structure 202, 203, 204, 206, M1, M2, which may be used for system qualification purposes, is provided in some of these through-openings. It is thereby possible in general to qualify the device 200 for analysing and/or processing a sample or the particle beam column 100 contained therein independently of a specific sample 13 or else independently of a sample stage 14. Instead, the shielding element 132 with its test structures may constitute a fixed reference. The test structures illustrated in FIG. 17 may provide different functions for ascertaining current operating parameters and/or process parameters of the device 200. The test structure 202 may for example comprise a topographic structure, various materials M1, M2 may be combined to form a test structure 203, it is possible to provide certain surfaces 204, 206 for performing particle beam-induced deposition processes and/or particle beam-induced etching processes, etc. It is also possible, for example, to provide a vibration element 208 having an exciter unit 160 and to draw conclusions regarding further operating parameters and/or process parameters of the device 200 on the basis of recorded vibration properties.

According to a further aspect of the disclosure, however, it is also possible not to install any separate elements as test structures 202, 203, 204, 206, 208, M1 or M2 in the openings 132 in the shielding element 130. Instead, it is possible to use a different type of shielding element 130 for qualification purposes:

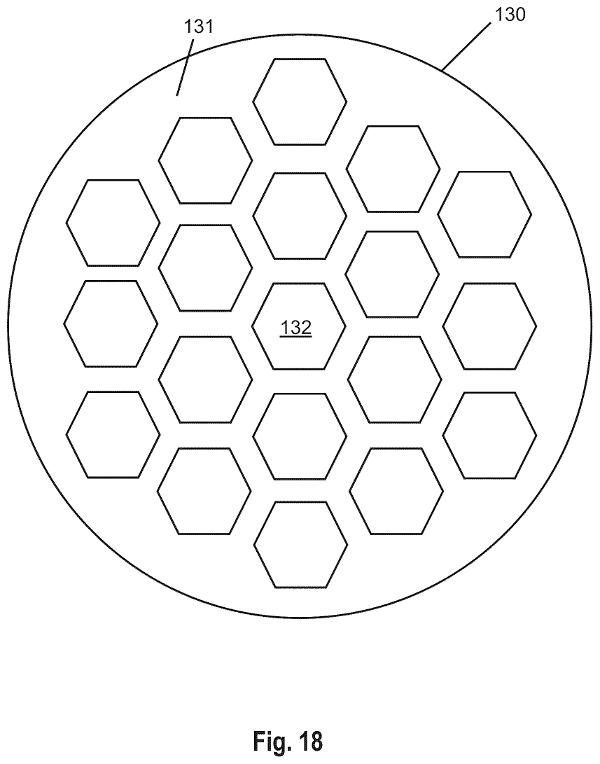

FIG. 18 schematically shows one such new shielding element 130. This in turn has a mesh structure 131 and, for example, interposed hexagonal openings 132. However, instead of then providing special structures in the openings 132, the mesh structure 131 itself is structured. This is indicated schematically in FIG. 18 by the hatching of the mesh structure 131. The otherwise very smooth and homogeneous structure of the mesh structure 131 itself may thereby be used for qualification purposes and/or adjustment purposes. An improved contrast ratio also arises in the region of the mesh structure 131 as a result of structuring, which significantly improves image evaluation.

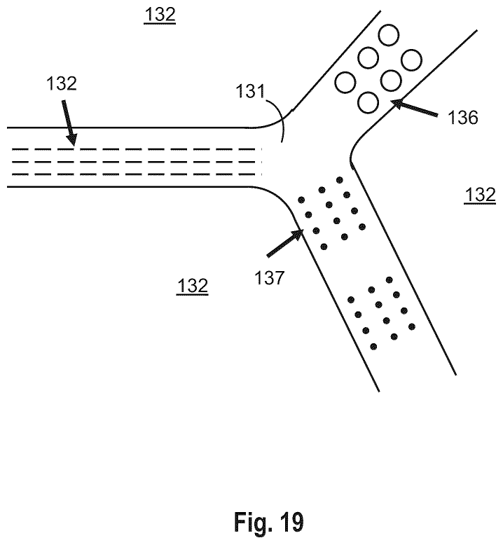

FIG. 19 schematically shows examples of such structuring on the mesh structure 131 itself. By way of example, a structure 135 in the form of spaced-apart parallel dashed lines is shown. In another limb of the mesh structure 131, a structure 136 having comparatively large circular individual structures is illustrated. In another limb of the mesh structure 131, a set of multiple smaller circles is illustrated as a structure element 137. The structures illustrated here should be understood only to be examples. In addition or as an alternative, it is also possible to use a pattern of randomly arranged circles or other shapes of randomly varying size as a structure. Such randomly/irregularly varying structures are helpful when identifying image aberrations, since the random structures only produce noise in a Fourier transform. They may be produced in various ways. By way of example, it is possible to apply the structures 135, 136, 137 on the mesh structure 131 directly by way of the device 200, for example with the aid of the process gas PG. It is also possible to modify and/or to remove these structures 135, 136, 137. As an alternative, it is also possible for the structures 135, 136, 137 to have already been applied to the shielding element or its mesh structure 131 in a separate manufacturing step, for example prior to assembly of the device 200. By way of example, this may be done by vapour deposition and/or etching or by ion-beam or electron-beam lithography methods.

According to an exemplary variant embodiment of the disclosure, all of the mechanical and/or electrical adjustment methods described in more detail above are performed not using a separate sample 13, but using a sample inherent to a device or particle beam column 100, such as for example the shielding element 130. It is thereby possible to implement a fixed reference for the adjustment routines and/or other qualification steps independently of a specific sample 13 and independently of a specific sample stage 14 and/or independently of a specific process environment, etc.

It is explicitly pointed out once again at this juncture that the embodiments of the disclosure that are described above should be understood only to be examples and in no way as restricting the disclosure.

### List of Reference Signs

1 Particle source
2 Suppressor electrode
3 Anode stop
3a Anode aperture
4 First condenser lens
5 First deflection unit
6 Condenser stop
6a Condenser aperture
7 Second deflection unit
8 Second condenser lens
9 Third deflection unit
10 Detection system
11 Magnetic objective lens
12 Electrostatic objective lens, end cap
13 Sample, object
14 Sample stage
20 Controller
30 Optical axis
40 Pole shoe
41 Pole shoe
42 Coil
50 Scanning device
80 Pole shoe
81 Pole shoe
82 Coil
100 Particle beam column, scanning electron microscope, SEM
110 Element to be adjusted of the particle beam column
111 Electrically driveable mechanical adjustment mechanism
112 Electrically driveable mechanical adjustment mechanism
113 Line
114 Line
120 Beam generators
121 Extractor stop
122 Particle beam
123 Particle beam
130 Shielding element
131 Mesh structure
132 Through-opening
133 Holder
135 Structure on the mesh structure
136 Structure on the mesh structure
137 Structure on the mesh structure
140 Housing
160 Exciter unit
170 Process gas supply unit
171 Process gas reservoir
172 Valve
173 Process gas line
200 Device for analysing and/or processing a sample
202 Test structure
203 Test structure
204 Test structure
206 Test structure
208 Vibrating element
211 Test structure
212 Test structure
310 Circle or circular ring
311 Detector hole of a secondary electron detector
312 Circle
313 Detector hole of a backscattered electron detector
314 Maximum
315 Maximum
316 Minimum
317 Sectional line
318 Dark background in a raster image
PG Process gas
M1 Test structure
M2 Test structure
Z Particle-optical axis of the particle beam column
x, y, z Directions

1. A method for mechanically adjusting a particle beam column, the particle beam column comprising: a beam generator having a particle source and having an extractor stop to generate a particle beam comprising charged particles; an anode stop; a condenser lens system to bundle the particle beam; a condenser stop to shape the particle beam; a first deflection unit to deflect the particle beam, the condenser stop between the anode stop and the condenser stop in relation to a particle-optical beam path of the particle beam column; an objective lens system to focus the particle beam onto an object, interaction particles arising when the particle beam interacts with the object; a detection system to detect the interaction particles; and a controller to control the particle beam column, wherein the method comprises for each of a plurality of different positions:
a) positioning the beam generator in a position using an electrically driveable mechanical beam head adjustment mechanism;
b) scanning the condenser stop with the particle beam using the first deflection unit and generating a raster image of the condenser stop using the detection system;
c) analysing the raster image with regard to the condenser aperture imaged thereon;
d) determining a best raster image based on the analysis or on the analyses according to c); and
e) positioning the beam generator, using the electrically driveable mechanical beam head adjustment mechanism, in a position in which the best raster image was generated.

2. The method of claim 1, wherein the best raster image is based on greatest intensity of the imaged aperture.

3. The method of claim 1, wherein the method is performed:
in a first stage and a second stage different from the first stage;
the first stage is in a) with a first step width over a first region; and
the second stage is in a) over a second region with a second step width, the second region being smaller than the first region, and the second step width being finer than the first step width.

4. The method of claim 1, wherein, during a), the beam generator is positioned in two mutually independent directions.

5. The method of claim 1, wherein the beam generator is displaced between different positions with a constant step width.

6. The method of claim 1, wherein an order in which the positions are moved to is defined before a), and wherein all of the positions are also actually moved to.

7. The method of claim 1, wherein the raster images are analysed after each displacement step and before the next displacement step, and wherein a step width and/or a step direction for the respectively next displacement step are/is ascertained adaptively based on the result of the analysis.

8. The method of claim 7, wherein the best position of the beam generator is a best position in the presence of at least one final termination criterion for a raster image.

9. The method of claim 1, further comprising:
varying a position of the particle source in the direction of a particle-optical axis of the particle beam column using an electrically driveable mechanical source adjustment mechanism to distance the particle source from the extractor stop;
measuring an extractor current in the respective position;
determining a best position based on the measured extractor currents; and
positioning the particle source in the best position using the electrically driveable mechanical source adjustment mechanism.

10. The method of claim 1, wherein the detection system is arranged within the particle beam column, and/or wherein the detection system runs annularly around an optical axis of the particle beam column.

11. The method of claim 1, wherein, during the method the particle beam column is operate, the condenser lens system is switched off; and/or the objective lens system is switched off.

12. One or more machine-readable hardware storage devices comprising instructions that are executable by one or more processing devices to perform operations comprising the method of claim 1.

13. A system, comprising:
one or more processing devices; and
one or more machine-readable hardware storage devices comprising instructions that are executable by the one or more processing devices to perform operations comprising the method of claim 1.

14. A method for mechanically adjusting of a particle beam column, the particle beam column comprising: a beam generator comprising a particle source and an extractor stop to generate a particle beam comprising charged particles; an anode stop; a condenser lens system to bundle the particle beam; a condenser stop to shape the particle beam; a first deflection unit to deflect the particle beam, the first deflection unit between the anode stop and the condenser stop in relation to a particle-optical beam path of the particle beam column; an objective lens system to focus the particle beam onto an object, interaction particles arising when the particle beam interacts with the object; a detection system to detect the interaction particles; and a controller to control the particle beam column, wherein the method comprises for a plurality of anode stop positions and a plurality of condenser stop positions:
a) positioning the anode stop in an anode stop position using an electrically driveable mechanical anode stop adjustment mechanism;
b) positioning the condenser stop in a condenser stop position using an electrically driveable mechanical condenser stop adjustment mechanism;
c) scanning the condenser stop with the particle beam using the first deflection mechanism and generating a raster image of the condenser stop using the detection system;
d) analysing the raster image with regard to the intensity and shape of the condenser aperture imaged thereon;
e) determining a best raster image based on the d); and
f) positioning the anode stop in a first position using of the electrically driveable mechanical anode stop adjustment mechanism and positioning the condenser stop in a second position using the electrically driveable mechanical condenser stop adjustment mechanism, wherein the first and second positions correspond to the positions of the anode stop and the condenser stop, respectively, in which the best raster image was recorded.

15. The method of claim 14, further comprising:
g) varying positions of the anode stop while keeping a fixed condenser stop position until the intensity of a generated raster image exceeds a fixed threshold value; and
h) after g), varying positions of the condenser stop while keeping a fixed position of the anode stop until the shape of the imaged condenser aperture has the greatest accuracy, a fixed position of the anode stop being the position of the anode stop in which the threshold value was exceeded during g);
i) after g), varying positions of the anode stop with a new fixed position of the condenser stop until the intensity of a generated raster image reaches a maximum, the new fixed position of the condenser stop being the position in which the greatest shape accuracy was ascertained during h); and
j) after i), varying positions of the condenser stop with a new fixed position of the anode stop until the shape of the imaged condenser aperture has the greatest accuracy, the new fixed position of the anode stop being the position of the anode stop in which the maximum intensity was reached during i).

16. The method of claim 15, wherein g), h), i) and j) are performed multiple times.

17. The method of claim 15, wherein g), h), i) and j) are repeated until a termination criterion for the intensity and/or the shape accuracy of the imaged condenser aperture is satisfied for a best raster image.

18. The method of claim 14, wherein:
during a), the anode stop is positioned in two mutually independent directions; and/or
during b), the condenser stop is positioned in two mutually independent directions.

19. The method of claim 14, wherein:
the anode stop is displaced between different positions with a constant step width; and/or
the condenser stop is displaced between different positions with a constant step width.

20-24. (canceled)

25. A method for mechanical adjustment of a particle beam column, wherein the particle beam column comprises: a beam generator comprising a particle source and an extractor stop to generate a particle beam comprising charged particles; an anode stop; a condenser lens system to bundle the particle beam, the condenser lens comprising first and second condenser lenses, the first condenser lens comprising first and second pole shoes, the first condenser lens being before the second condenser lens along a particle-optical beam path of the particle beam column; a condenser stop to shape the particle beam, the condenser stop being between the first and the second condenser lens; an objective lens system to focus the particle beam onto an object, interaction particles arising when the particle beam interacts with the object; a scanning device to deflect the particle beam and to scan the object, the scanning device being after the condenser stop along the particle-optical beam path; a detection system to detect the interaction particles; and a controller to controll the particle beam column, wherein the method comprises:
a) positioning the first condenser lens in a condenser lens position;
b) exciting the first condenser lens using a first weak excitation strength and wobbling the condenser lens excitation or wobbling an acceleration voltage of the beam generator;
c) generating multiple raster images using the detection system during wobbling, for each raster image, the particle beam being raster-scanned over the object using the scanning device;
d) determining a displacement of the emission spot imaged in the raster images during wobbling;
e) repeating b) to d) and, during this, varying a position of only the first pole shoe of the first condenser lens using an electrically driveable mechanical first pole shoe adjustment mechanism;
f) ascertaining a position of the first pole shoe in which a displacement of the emission spot in the raster images is reduced; and
g) positioning only the first pole shoe in the position ascertained in f) using the electrically driveable mechanical first pole shoe adjustment mechanism.

26-51. (canceled)
